(19) United States
(12) Patent Application Publication
(10) Pub. No.: US 2009/0021598 A1
(43) Pub. Date: Jan. 22, 2009

(54) Miniature integrated multispectral/multipolarization digital camera

(76) Inventors: John McLean, Tucson, AR (US); Gary Redford, Tucson, AR (US)

Correspondence Address: PETER I. LIPPMAN, 17900 MOCKINGBIRD DRIVE, RENO, NV, 89508, US

(21) Appl. No.: 12/157,008

(22) Filed: Jun. 6, 2008

(30) Foreign Application Priority Data
Dec. 6, 2006 (US) PCT/US2006/046535

(51) Int. Cl. H04N 5/222

(52) U.S. Cl. 348/222.1; 348/E05.022

(57) ABSTRACT

Several aspects of the invention respectively record one or more multispectral (MS) images using at least one sensor array, each array getting one respective image and simultaneously polarization state at the array points; and get and displays a MS, multipolarization (MP) movie, at MS/MP frame rates that suit a scene or the acquisition; and get an MS image, and a polarization-state image, so that the two are inherently in register; and provide a digital camera for plural-waveband imaging, including polarization data, using a chip with an optically sensitive layer continuously spanning a field of view—for each of at least two substantially distinct bands, and with stacked layers, some radiation penetrating plural layers to a corresponding sensitive layer, and with a polarization mosaic over the stack to define a superpixel array that differentiates polarization states, and with an electronic shutter actuating the layers. Another aspect makes a time sequence of registered MS/MP images; and yet another gets data for one or more MS images, including polarization state at most image points, via a single, common aperture.

This document claims priority of U.S. provisional patent application 60/749,125, filed Dec. 9, 2005; and of international application PCT/US2006/046535, filed Dec. 6, 2006—both of which are wholly incorporated by reference into this document.

### RELATED DOCUMENTS

Related documents include International Publication WO 01/81949 of Anthony D. Gleckler, Ph. D. and Areté Associates (of Northridge, Calif.; Tucson, Ariz.; and Arlington, Va.)—and other literature and patents, some of which are cited therein, of Areté Associates on passive and active imaging. Also related are U.S. Pat. Nos. 6,304,330 and 6,552,808 of James E. Millerd and Neal J. Brock. Still other related documents are listed at the end of the “DETAILED DESCRIPTION” section of this document. All are wholly incorporated by reference into this document.

### FIELD OF THE INVENTION

The invention is in the field of detecting and identifying objects against extremely complicated backgrounds, i. e. in complex environments. This function may alternatively be described as “discrimination” of objects and backgrounds.

The field of the invention thus potentially spans applications in the medical, commercial, ecological and military imaging areas. The invention particularly addresses techniques of multispectral imaging and multipolarization imaging, and ideally at wavelengths from the ultraviolet to the infrared.

### BACKGROUND

Imaging systems—Object detection and identification in complex environments requires exploitation of multiple discriminants, to fully distinguish between objects of interest and surrounding clutter. For passive surveillance, multispectral, hyperspectral, and polarization imaging have each shown some capability for object discrimination.

Polarization provides, in particular, a powerful discriminant between natural and manmade surfaces¹. Thus an unpolarized view (FIG. 1B) fails to accentuate artificially created features that appear extremely bright in a polarized view (FIG. 1A).

(Some natural features too interact distinctively with polarized light, particularly features that reflect with a significant specular component e. g. due to liquid or waxy content. Such features of course include bodies of water, but also many broad-leafed plants [FIG. 19]. Other foliage, such as for instance trees with waxy but fine needles, generally have randomly oriented polarizations for adjacent elements—and so return only a very weak polarization signature.)

Simple estimates, however, indicate that use of either spectral or polarization technique alone suffers a very distinctly limited discrimination capability. For instance a recent article on the polarization properties of scarab beetles shows that the polarization properties are wavelength dependent.

Thus, neither measurement of spectral properties nor of polarization properties alone can completely characterize the optical signature. “Polarization properties of Scarabaeidae”, Dennis Goldstein, 45 Applied Optics No. 30 (Oct. 20, 2006).

Part, but only part, of the reason for this limitation resides in the unfortunately large sizes and weights of currently known independent spectral and polarization packages. Such bulks and weights must be aggregated to obtain both of these capabilities together, in coordination.

Typically the modern observational packages occupy more than 65 in.³ and add payload of five or six pounds, each. As these units are not designed to fit together, the effective aggregate volume may typically come to over 80 in.³.

In the military context, these requirements alone are relatively onerous for small unstaffed (i. e., so-called “unmanned”) aerial vehicles (UAVs) such as Dragon Eye and Silver Fox—and the result is to deny unit commanders an organic, real-time reconnaissance and surveillance capability. Similarly limited are existing UAV-based passive mine-detection systems such as those known by the acronyms COBRA and ASTAMIDS.

In the commercial/medical context, analogously, the development of spectral and polarization equipment separately has kept overall costs for the two capabilities somewhat in excess of $50,000. As a consequence these devices, paired, are not generally to be found in medical diagnostics—even though they have been demonstrated as an effective diagnostic tool for early detection of skin cancer (melanoma). Likewise these devices are not significantly exploited for industrial process control (finish inspection and corrosion control), or land-use management (agriculture, forestry, and mineral exploration).

Much more severe, however, than the above-discussed system volume, weight and cost burdens are key technical limitations that actually obstruct both high resolution and high signal-to-noise in overall discrimination of objects of interest against complicated backgrounds. Multispectral and multipolarization data provide complementary measurements of visual attributes of a scene, but when acquired separately these data are not inherently correlated—either in space or in time.

To the contrary they are subject to severe mismatches. These are due to the involvement of multiple cameras, multiple image planes, and multiple exposures—each with their own required exposure times—for different wavelengths and different polarization states.

Realization of the ultimate discrimination capability provided by these multidimensional imaging systems is dependent upon precise spatial and temporal registration of the several spectral and polarization data sets. Simple estimates for key environments (particularly ocean-submerged objects) suggest that the penalty paid in attempts to integrate such disparate data sets, after initial acquisition by physically separate systems, probably amounts to a discrimination loss of 25 to 35 dB or more.

In purest principle, under ideal circumstances such registration defects can be removed during postprocessing. As a matter of actual practice, however, the ideally required subpixel registration is both computationally expensive and difficult.

Sometimes adequate registration is simply intractable, as in the case of sequential exposures from a moving vehicle. In this case, small differences in the exposure times for the different spectral bands can yield corresponding data subsets with incompatible camera positions and orientations.

Such timing differences in turn are attributable to imperfect time sampling by, for example, spinning filter wheels. Spinning filters are familiar in this field.

Even though this problem arises most proximately from such imperfect time samplers, there is a more fundamental cause. It is that (as suggested above) the data subsets are acquired separately, and by sensing modules that are not inherently correlated.

Residual errors of registration thus persist, and yield the above-noted very significant degradations in expected processing gain. Efforts to overcome these compromised fundamental performance parameters in turn lead to increased system complexity—with attendant size, weight, power, and reliability problems.

Imaging sensor—Commercially available devices of interest in addressing these problems (but not heretofore associated with them) are single-chip multispectral imaging arrays operating in the visible and infrared bands. As an example of arrays that are now commercially available for the visible- or near-visible range, one such device is a single-chip, direct-imaging color sensor², model “Foveon X3” from Foveon Inc. of Santa Clara, Calif. The firm was founded in 1997 by Dr. Carver Mead, a pioneer in solid-state electronics and VLSI design, and professor emeritus at the California Institute of Technology.

As with the layers of chemical emulsion used in color film, Foveon X3 image sensors have three photosensitive layers—but in the X3 these are digital materials, so that images are captured as pixels at the outset. The layers of sensor pixels 61c, 61b, 61a (FIGS. 9A, 9B) are embedded in silicon to take advantage of the fact that red light 48c, green light 48b and blue light 48a penetrate silicon 61 to different depths.

Thus full color is separated in a natural way, and recorded digitally at each point in an image. Since the sensor set 61a, 61b and 61c (FIGS. 9C, 9D, 9E) for each color range is uninterrupted by sensor pixels for other colors, this CMOS device provides high resolution (10 megapixels: 2268×1512×3 bands).

Earlier conventional imaging chips give up a resolution factor that is, on average, between two and three—because the three sensor sets 71c (FIGS. 10A, 10B), 71b and 71a are distributed laterally to form a single, common, shared sensor layer above a base 75. Each of the three sensor sets 71c, 71b, 71a (FIGS. 10C, 10D, 10E) is necessarily restricted to occupy only a portion of the common sensor layer.

More specifically, such earlier conventional chips are usually formed according to a so-called “Bayer filter” principle, in which the green-sensitive pixels 71b (FIGS. 10A, 10B, 10D) are in a checkerboard pattern—and thus occupy half the total area of the composite sensor array. The remaining half of the area is shared, usually equally, by the blue- and red-sensitive pixels 71a, 71c respectively (FIGS. 10C, 10E). This distribution of sensitivity emulates very roughly the sensitivities of the human eye in the respective spectral regions of the primary colors.

Analogous pixel layouts are also known for multiple wavelength bands running out to the far infrared. Association of such pixel configuration with polarization sensing, however, has not previously been suggested.

It is also known to use active monochromatic illumination and, from that excitation, to collect returns that are either multipolarization or multispectral. It has not been suggested to collect both.

The Foveon X3 image sensor yields extremely high dynamic range (12 bits) and wide spectral bandwidth (350 to 1110 nm)—well beyond both ends of the visible range. It is now marketed in an integrated camera system (FIG. 8), complete with USB 2.0 interface³.

TABLE 1
Foveon ® X3 direct imaging sensor characteristics

| parameter | values |
|---|---|
| spatial resol'n (pixels) | 2268 × 1512 |
| pixel size (μm) | standard 9.12 square |
| spectral channels | three, each with its own 24 MHZ clock |
| power required (mW) | 80, full-frame readout |
| focal-plane array | single (no filter, splitter, etc.-thus |
| | achieving lower cost, volume and weight) |
| optional modes | region of interest (ROI) and binning, for |
| | higher frame rate |
| transient-event capture | single-shot RGB: no sequential frame stacking |
| spatial sampling | full (no gaps in the image) |
| spectral responsivity | 350 to 1110, limited only by theoretical |
| (nm) | silicon band gap and oxide layer penetration |
| well capacity (electrons) | maximum 231,000/pixel, 77,000/diode |
| target SNR | high, due to high well capacity |

This sensor thus provides multispectral imaging without any of the spatial registration and aliasing problems encountered in more-familiar multiCCD and Bayer-type color cameras. It has never before been associated with polarization imaging as such—or with the above-detailed problems presented by separate spectral and polarization imaging. Specifications of the X3 chip appear in Table 1, above.

The table mentions “binning”, which is a clocking system that combines charge collected by plural adjacent CCD pixels. It provides a tradeoff of resolution to reduce photon noise and thereby improve the signal-to-noise ratio—while also advantageously raising the frame rate.

The Foveon-style array is sensitive from the ultraviolet into the near infrared. Single-chip multispectral imaging arrays are also available farther into the infrared, and dual-band focal-plane arrays are currently available across the mid- and long-wave bands.⁴

Camera package—A related commercially available device, never before associated with polarization imaging as such—or with the problems of separate spectral and polarization imaging discussed above—is a product of Optic Valley Photonics (OVP) of Tucson, Ariz. OVP's Opus I item is a digital color camera based on the Foveon X3 chip and including a USB 2.0 interface. Opus I specifications appear in Table 2, below.

TABLE 2
Opus I ® camera characteristics

| parameter | values |
|---|---|
| diodes | 3/pixel |
| well capacity (electrons) | maximum 77,000/diode, 231,000/pixel |
| | typical 45,000/diode, 135,000/pixel |
| spectral channels | 3/pixel |
| effective samples (total) | 2268 × 1512 × 3 |
| effective photodiodes | 10.3 million |
| pixel pitch (μm) | 9.12 |
| effective image area (mm): | |
| sides | 20.68 × 13.79 |
| diagonal | 24.86 |
| quantum efficiency (electrons) | 0.6/photon (peak, at 625 nm) |
| fill factor, with microlens | 70% |
| data/control | USB 2.0 (other interfaces are possible) |
| frame sync (ohms) | 50 (SMB plug receptacle) |
| sync/trigger | output or input |
| frame rate (Hz): | |
| full frame | >1, full resolution, 16 bit packing |
| subframe | >2, ROI (selectable) |
| binned | >2 (1 × 2, 4 × 4, selectable) |
| power: | |
| input voltage required (Vdc) | 6 ± 5% |
| consumption (W) | typical 4 |
| weight (pounds) | |
| card set | 0.15 |
| housing | 0.90 |
| total | 1.05 |
| card-set size (inches) | 3.4 × 3.4 × 0.5 |

Polarization arrays—Two kinds of devices have been successfully used to provide polarization discrimination for a panchromatic imaging sensor. One of these is an achromatic spectrally neutral beamsplitter, combined with multiple imaging arrays.

The other is a micropolarizer array, or so-called “polarization mask”, coupled to a single imaging array. Neither of these devices has ever before been associated with multispectral imaging as such—or with the above-detailed problems of separate spectral and polarization imaging.

In the beamsplitter approach a spectrally neutral prism forms four image planes, each then coupled to its own imaging array 42a, 42b, 43c (and a fourth array, not shown—FIGS. 2 and 3). These prisms are commonly used in multichip color cameras, but also are successfully used in panchromatic polarization imaging⁵—with a differently oriented polarization filter 43a, 43b, 43c (and a fourth filter, not shown) at each of the four imaging arrays.

A prismatic beamsplitter approach can be replaced by techniques using e. g. a dichroic splitter. Information on such dichroic units is currently seen on the Worldwide Web at http://www.cvilaser.com/Common/PDFs/, particularly in this file there: “DichroicBeamsplitters_Discussion.pdf”.

Each output stage 44a, 44b, 44c, 44d (FIG. 3) of the splitter prism also has an associated micropositioner 41a, 41b, 4c (and a fourth positioner, not shown, for a fourth wavelength band—FIG. 2). The system also includes image relay optics 45, a zoom lens 46, and a bandpass input filter 47 for the entering radiation 48.

Following the optics 45, in multispectral applications the radiation 48′ entering the compound prism 44a-b-c-d is split to form four output beams 49a-b-c-d, conventionally passed through color filters 42, as noted above, to form red 49a, green 49b, blue 49c and infrared 49d beams. In known multipolarization systems the beams are passed through polarization filters instead, to form beams of differently oriented polarization.

While certainly feasible, the polarization-array architecture under discussion appears to be relatively complex, expensive, and heavy. In addition, pixel registration (discussed above) for multichip systems has proven to be very difficult.

Only 0.5-pixel registration has been demonstrated to-date, and this would represent significant compromise of postprocessing gain. The polarization-mask approach appears superior, and will be detailed below.

Polarization-mask fabrication—Two techniques in turn are now used to make polarization masks: a one-layer, wire-grid array (process layer, FIGS. 5 and 6B), and a multilayer thin-film method (FIG. 6C). Wire-grid arrays have been successfully fabricated to 9 μm pixel pitch in arrays more than 1000 pixels square⁶.

Here the linear polarizers are oriented at 0, 45, 90, and 135 degrees—as at 51, 52, 54 and 53 respectively (FIG. 4). This existing wire-grid polarizer uses 70 nm wires 56 (FIG. 5) at 140 nm spacing. Radiation 48″ passes through the wires and a substrate 57 to a detector 58.

For best polarization contrast, the spacing of the wires 56 should be quite small relative to the optical wavelength. Accordingly, while this existing design provides outstanding polarization contrast in the middle of the visible band (very roughly 600 nm), polarization contrast is e. g., expected to degrade at shorter visible wavelengths—where the spacing becomes as much as 35% of the wavelength.

Alternatively, micropolarizer devices for the visible spectrum have been successfully fabricated using polarizing thin films in a multilayer configuration, and such arrays have been successfully bonded to CMOS arrays⁷ (FIG. 6C). The demonstrated device was based on a 13.8×14.4 μm pixel pitch and formed as a 352×288 pixel array. In addition, polarization masks have been constructed to a pixel pitch as fine as 5 μm.

As is well understood in this field, equivalent or complementary polarization definition can be accomplished by various combinations of linear and circular polarizers, neutral filters and so on. The polarizer-mosaic representations (FIGS. 4, 6, 11, 12 and 15), shall accordingly be understood to alternatively represent such other conventional polarization elements.

Microlens array—Yet another known technology that has not previously been associated with multipolarization imaging is the use of microlenses to correct poor CCD illumination geometry. The ratio of the photosensitive area of a detector pixel to the total pixel area (e. g. square) is called the “fill factor”, and is less than unity for many imaging arrays.

In such cases, photons which fall upon a nonsensing portion (e. g. corner) of the pixel are not detected, resulting in an area-proportional loss of radiometric sensitivity. In some known multispectral imaging systems of the Bayer type, such a loss is overcome by including a microlens array in front of the imaging array: an individual lenslet, ideally one in front of each pixel, focuses or at least concentrates the incoming radiation into the sensitive area of the pixel. This is known for Bayer sensor layouts, where light of e. g. blue 71a, green 71b and red 71c (FIG. 13) is selectively admitted by corresponding filters 82, but blocked spatially by an opaque metal layer 83.

So that the blocked outboard rays can reach the underlying photodiodes 84, each sensor is fitted with a corresponding lens 81a, 81b, 81c—all the lenses being formed in one piece as an array, fixed across the entire surface of the imaging array. The lenses are most typically integrated with the rest of the assembly, on the silicon substrate 85, to enhance radiometric efficiency of the multispectral imaging sensors.

Differencing display—A prior-art technique not previously associated with multispectral imaging is polarization-difference display. The goal here is to exploit as much as possible the capability of images made by polarized light to discriminate between manmade and natural objects.

Polarized-light images, however, differ conspicuously not only from unpolarized-light images but even more notably from each other. That is, source illuminations whose polarizations are crossed or aligned relative to inherently polarizing axes of object surfaces, can produce optical extinction or full transmission, respectively.

If the axes of the illumination and the object surfaces do not happen to be optimally crossed or aligned, however, such visually striking clues may not appear. Difference display sometimes helps to overcome this limitation.

For example, two images of a single, common scene can be recorded in horizontally (FIG. 14A) and vertically (FIG. 14B) polarized light respectively. Viewing each of these images alone, or even inspecting them side by side, may not suffice to pick out e. g. machinery concealed under foliage.

Enlargement of the ROI (FIG. 14C) is likewise inadequate. If the difference between the light levels in the two polarized-light images is displayed, however, sometimes very obvious signatures appear—signaling the presence of artificial surfaces.

In fact when this kind of display is used, one remaining awkwardness is simply lack of positional reference. That is, although the signatures are very clearly defined it is not intrinsically clear where they are with respect to the original scene.

This problem can be mitigated by superposing a copy of that original scene, for reference, onto the displayed difference image. The difference image and the overlaid reference copy are preferably in contrasting colors, to minimize confusion of the positional-reference information with the difference signatures. Since prior-art usage of polarization-difference display has been for monochromatic (or panchromatic) imaging only, the colors used are simply any convenient so-called “false colors” chosen arbitrarily by the designers or the operator.

Thus for example the polarization-difference signatures 101 (FIG. 14D) may be caused to appear in dark red and the position-reference information in a light blue. If the reference is made light enough to avoid obscuring the difference signatures, then unfortunately it can be difficult to clearly see locations in the reference overlay.

Moreover, there is a more basic limitation. As mentioned above, the difference signatures are very obvious only sometimes. The extent to which they stand out well depends on the relationship between the orientations of (a) the polarizing surfaces in the scene and (b) the two crossed polarization states that are used in recording the images. This relationship is somewhat controllable, but at the cost of additional time to determine the ideal (maximum contrast) orientations for the scene.

In general, ideal orientations for different objects in the same scene are at least slightly different, so that no single best solution exists for the entire scene. Finally, the false color required for clear discrimination of positional overlay from difference signatures militates against use of this difference technique in multispectral imaging.

Other known display techniques—At least one research group²² reports canvassing of a number of other, far more sophisticated techniques that exploit dynamic display characteristics, and corresponding dynamic capabilities of human vision, to render polarization-difference signatures conspicuous—and to suggest roughly some quantitative characteristics of those signatures. This reported work, of Konstantin Yemelyanov et al., makes use of multipolarization and multispectral data, acquired in some unspecified way or ways; it does not teach any described technique for acquiring such data.

Several of the innovative techniques described appear to be unsuited to the problem discussed above (FIG. 14), because the signature cueing mechanics require relatively broad display-screen areas. Unfortunately, a particular object or surface 101 of interest may be quite small.

In some cases Dr. Yemelyanov's cueing mechanisms (e. g., so-called “coherent dots”) may entirely obscure a small feature. In other cases the feature 101 may be somewhat visible behind and around the cueing symbols, but with not enough image area to meaningfully exhibit crucial aspects of the cues (e. g. coherent motion of multiple dots, or other directional representations).

More relevant to the present invention are Yemelyanov's innovations in temporal modulation of image elements—rendered in terms of polarization differences or sums, or both. Some of these techniques involve opposed modulation of the polarization difference and sum signals, in which one such signal fades into the other, and then back, at mentioned frequencies between 1 and 15 Hz.

The paper was accompanied by videos showing these counterfades, with false color designating polarization signatures, over an entire cycle of this flicker-like display method. Still frames extracted from such videos at the beginning of the cycle (phase zero, FIG. 19A) and about halfway through (phase roughly 180 degrees, FIG. 19B) show the general methodology.

The color in these particular examples is not natural scene color, and would interfere with viewing of natural-color scenes—at least to the extent that such coloring is applied to unpolarized (or so-called “polarization sum”) image areas. Therefore this specific technique is not appropriate for use with full natural multispectral, multipolarization data; however, certain of Yemelyanov's other cue techniques may serve well. In addition he introduces the idea of radiometric balancing of images taken with differently polarized light, particularly histogram balancing.

Yemelyanov refers to some of his dynamic displays as motion pictures or movies. It will be understood, however, that the movement shown in these displays is not natural movement of scene elements. Rather, all the movement seen is variation of image detail due only to the graphical “cues” injected into the data for the specific purpose of visualizing polarization relationships.

Yemelyanov does not suggest that multispectral, multipolarization data can be acquired in synchronism and spatial register. He does not advocate any data-acquisition method at all.

Conclusion—Thus in medical, commercial, ecological and military imaging alike, separate paths of development for multispectral and multipolarization technologies have actually obstructed optimization of overall object-discrimination capabilities. Furthermore some superlative optical innovations have never been brought to bear on the highest forms of the problem of detecting and identifying objects in complex environments.

Accordingly the prior art has continued to impede achievement of uniformly excellent object discrimination. Thus important aspects of the technology used in the field of the invention remain amenable to useful refinement.

### SUMMARY OF THE DISCLOSURE

The present invention introduces just such refinement. In preferred embodiments the invention has several independent aspects or facets, which are advantageously used in conjunction together, although they are capable of practice independently.

In preferred embodiments of its first major independent facet or aspect, the invention is apparatus for multispectral and multipolarization imaging. The apparatus includes first means for recording at least one multispectral image of a scene. For breadth and generality in discussing the invention, later passages in this document may refer to these means as the “recording means”. For purposes of this document and particularly the claims presented, a multispectral image includes multiple different wavelengths or colors.

The recording means include some means for discriminating among at least some of the multiple different wavelengths or colors in the scene. Thus later passages alternatively may refer to these means as the “recording and discriminating means”.

The recording and discriminating means include exactly one array of sensors. Accordingly the sensor array records one multispectral image of the scene. The recording and discriminating means include some means for recording all pixels of the multispectral image mutually simultaneously.

The apparatus also includes second means for, simultaneously with the recording, determining polarization state of the image at corresponding points of the exactly one array. In the apparatus, the first and second means operate using radiation collected through a single aperture, in common. For purposes of this document, and particularly the claims, a “single aperture” is an aperture that does not have plural optical apertures in parallel.

The foregoing may represent a description or definition of the first major independent aspect or facet of the invention in its broadest or most general form. Even as couched in these broad terms, however, it can be seen that this facet of the invention importantly advances the art.

In particular, by collecting all the optical information through a common aperture—and onto a single common sensor array, together with polarization state, and all simultaneously—this first facet of the invention eliminates problems of distortion and alignment, and sidesteps difficulties with synchronicity, that have bedeviled the prior art. This aspect of the invention also represents a further significant advancement in that it not only receives and responds to multiple spectral components (and polarization states) but also, as explicitly recited in the above definition or description, discriminates among those components. More generally, this first facet of the invention brings together for the first time several previously separate developments in multispectral and multipolarization detection. The result is to very greatly enhance the core capability of discriminating objects and backgrounds.

Thus the first major aspect of the invention is able to report spectral distributions of the optical characteristics involved. This too is accomplished without sacrificing any of the advantageous single-aperture, single-sensor-array, synchronous character of the apparatus. The prior art never suggests how to accomplish such feats or even that they can be accomplished, in any way.

Nevertheless to optimize enjoyment of its benefits preferably the invention is practiced in conjunction with certain additional features or characteristics. In particular, here are several basic preferences, relative to the above-described broadest form of the invention:
the collected radiation is incoherent radiation; and the apparatus includes no radio-frequency modulator, and no means for vibrationally inducing diffractive fringes;
the apparatus further includes some means (in this document, “display means”) for successively presenting the multispectral image with different polarization-state information included—so that image portions having polarization states different from one another appear to flicker;
the apparatus still further includes some means for trading-off resolution (which this document will call “trading-off means”) against frame rate, for acquisition of multiple sequential image data sets corresponding to a motion picture—and the trading-off means in turn include some means for increasing resolution while decreasing frame rate, or increasing frame rate while decreasing resolution, to maintain generally constant total information acquired per unit time—and in addition the apparatus includes some means for controlling frame acquisition rates of the acquisition means, in accordance with characteristics of the scene or of the acquisition process; in the case of this particular preference, the collected radiation is substantially ambient radiation (this last-mentioned condition, as will appear, if desired can be associated with almost any other features of the invention);
the exactly one sensor array includes multiple sensor-array planes, responsive in multiple spectral regions respectively, for recording the one image as substantially a single array of pixels, and for spectrally analyzing the multispectral image; and the second means include means for selecting or defining a different polarization state for different regions of the image respectively—and these second means determine and record polarization state at substantially every pixel of the multispectral image;
if this above-defined second basic preference is observed, then these subpreferences come into play: the multiple sensor-array planes are permanently in contact with each other and therefore inherently in register with each other; and the selecting or defining means are permanently in contact with the exactly one sensor array and therefore inherently in register with the exactly one sensor array;
nested with the subpreference just described: the selecting or defining means include at least one mosaic of differently oriented polarizers overlaying the sensor array;
given this sub-subpreference, a further-nested set of alternative preferences is that: the polarizer mosaic be formed as a wire-grid array; or the mosaic be formed of polarizing thin films; or the single, multispectral sensor array include plural sensor-array layers respectively responsive to plural wavelength regions or colors; or the mosaic include a combination of linear polarizers and neutral-density filters; or the mosaic include a combination of linear and circular polarizers, and neutral-density filters; or the mosaic be formed of multiple unit cells, each unit cell being three pixels; or that the mosaic be bonded to the sensor array; or that the mosaic be lithographically integrated into the chip, in fabrication; or that it include microlenses incorporated to enhance fill factor or reduce aliasing, or both;
in this last mentioned case of incorporated microlenses, a still further preference is that the polarizer mosaic includes spectral filters incorporated to optimized spectral response;
when the sensor array has plural sensor layers responsive to respective wavelength regions or colors, and is overlain by a mosaic of differently oriented polarizers, then in turn preferably the mosaic is formed of multiple unit cells, each unit cell being two pixels by two pixels, and the two-by-two unit cells include linear polarizers—and in this case a further preference is that the linear polarizers be oriented at zero, forty-five, ninety and one hundred thirty-five degrees respectively;
in the case of the three-pixel multiple-unit-cell preference, then preferably each three-pixel cell includes linear polarizers or, alternatively, each three-pixel cell includes a combination of linear polarizers and neutral-density filters; or includes a combination of linear and circular polarizers and neutral-density filters.

The above discussion to registration bears additional comment: in many applications, registration is a critical parameter for satisfactory discrimination of objects and backgrounds in a multispectral, multipolarization system; and, as suggested earlier, registration has been a limiting factor even in multipolarization, single-spectral-band systems. In this document we teach how to provide fully adequate registration for multipolarization, multispectral imaging.

In preferred embodiments of its second major independent facet or aspect, the invention is apparatus for acquisition, and preparation for display, of a multispectral, multipolarization motion picture. The apparatus includes some means for acquisition and recording, through a single optical aperture, in common, of successive multispectral, multipolarization image frames. In this document, again for the sake of breadth and generality, such means are called “acquisition-and-recording” means. Analogously to the discussion of the first main aspect, above, a multispectral, multipolarization image frame is an image frame including multiple different wavelengths or colors and plural polarization states; and a single optical aperture is an aperture that does not include plural optical apertures in parallel—but the single aperture can have plural optical apertures in series.

The acquisition-and-recording means include means for discriminating among at least some of the multiple different wavelengths or colors in the image frames, and among at least some of the polarization states in the image frames. The apparatus also includes some means for controlling frame acquisition rates—again, “rate-controlling means”—of the acquisition means, in accordance with characteristics of the scene or of an acquisition process.

The foregoing may represent a description or definition of the second aspect or facet of the invention in its broadest or most general form. Even as couched in these broad terms, however, it can be seen that this facet of the invention importantly advances the art.

In particular, this main aspect of the invention adds a major advance in the field of polarization-based discrimination of objects from backgrounds: this aspect of the invention, in its fundamental form, encompasses the critical subsystem for display of the information. Moreover that display provides color motion pictures.

Color-movie display enlists the very sensitive human perception capability to detect small objects that are moving, even slightly, against a background. This capability is particularly powerful when the objects may also have color differences, even subtle ones, relative to the background.

This human perceptual capability has not previously been exploited in polarization-based detection. Very importantly, however, this facet of the invention acquires data frames at rates adapted to the character of the scene, or of the process used for acquisition.

In particular, people skilled in this field will now appreciate that this aspect of the invention extends most of the benefits of the above-discussed first main aspect—from imaging generally, to imaging in motion pictures. Equivalently, the benefits are extended to imaging collected as a multiplicity of data sets, most typically aggregated in succession so that if desired a motion picture can be prepared and displayed from the overall group of data sets.

Another very significant advantage conferred by this second major facet or aspect of the invention is that acquisition of image frames is not at all limited or constrained to acquisition rates in accordance with display rates, or the characteristics of equipment for showing motion pictures, or in accordance with visual abilities of people who may later wish to view the aggregated frames—i. e., to “playback” requirements. Instead this facet of the invention is decoupled from such requirements, offering great freedom to, for example, optimize acquisition rates for best acquisition results as such.

People skilled in this field will recognize, however, that playback nevertheless can be conditioned to any of such playback parameters if desired or preferred. Just such an arrangement will be introduced shortly.

Although the second major aspect of the invention thus significantly advances the art, nevertheless to optimize enjoyment of its benefits preferably the invention is practiced in conjunction with certain additional features or characteristics. In particular, preferably the recording and discriminating means include means for recording all pixels of the multispectral image mutually simultaneously. Another preference is that the apparatus include no means for vibrationally inducing diffractive fringes, and no radio-frequency modulator.

Another preference is that the acquisition-and-recording means—which as noted earlier include a single, multispectral sensor array—nevertheless include plural sensor-array layers, respectively responsive to plural wavelength regions or color bands; and further include some means for playing back the recorded frames for human observation. The latter means, which this document hereinafter calls “playback means”, have a characteristic that is quite useful and has already been foretold above: these playback means include means for controlling frame display rates in accordance with perceptual characteristics of human observers of the motion picture. (Thus these playback means enjoy a benefit that is the converse of the recording-and-discriminating means stated above—namely, that the playback means are not constrained to be compatible with the recording-and-discriminating means, but rather are isolated and decoupled from those latter means. The playback means therefore are freely optimized for best playback parameters and best playback quality.)

In yet another basic preference, still with reference to the second main facet of the invention, the playback means further include some means (hereinafter “display means”) for successively presenting the successive image frames with different polarization-state information included. In such presentation, the multiple different wavelengths or colors sensed by the plural sensor-array layers are respectively presented by the display means as spectrally corresponding multiple wavelengths or colors in each image frame. In this preference, image portions having polarization states different from one another appear to flicker.

In preferred embodiments of its third major independent facet or aspect, the invention is apparatus for multispectral and multipolarization imaging; the apparatus includes first means, operating with substantially only ambient radiation, for recording a multispectral image of a scene. As before, in this document these first means may be denominated “recording means”; and a multispectral image is an image including multiple different wavelengths or colors.

In this apparatus of the third major aspect or facet of the invention, the recording means include some means for discriminating among at least some of the multiple different wavelengths or colors in the scene. These means we may call “discriminating means”.

This same apparatus also includes second means, also operating with substantially only ambient radiation, for establishing a polarization-state image of the same scene. Herein we may call these second means “polarization-state image establishing means”. The first and second means share a common radiation-sensor array.

The foregoing may represent a description or definition of the third aspect or facet of the invention in its broadest or most general form. Even as couched in these broad terms, however, it can be seen that this facet of the invention importantly advances the art.

In particular, besides having most of the same benefits mentioned above for the first and second main facets of the invention, this third facet is not limited to use in so-called “active” optical systems. In other words, explicitly this facet of the invention functions with ordinary ambient radiation (illumination)—and thus does not require excitation-and-response schemes such as used in e. g. lidar, in interferometry, and in other reply-based measurement technologies.

Although the third major aspect of the invention thus significantly advances the art, nevertheless to optimize enjoyment of its benefits preferably the invention is practiced in conjunction with certain additional features or characteristics. In particular, preferably the first and second means further are functionally coordinated to render the inherently-in-register polarization and multispectral images mutually simultaneous.

Another preference is that the common array be a monolithic device that causes the polarization image to be inherently in register with the multispectral image. A further preference is that the first and second means respectively provide spectrally-selective and polarization-selective elements to modulate response of the shared common radiation-sensor array.

A still further preference is that the first and second means collect all of the multispectral image and all of the polarization-state image through a single, common aperture—i. e., that the single aperture does not include plural optical apertures in parallel, though it can have plural optical apertures in series. Yet another preference is that the recording and discriminating means include means for recording all pixels of the multispectral image mutually simultaneously. Moreover another preference is that the apparatus include no means for vibrationally inducing diffractive fringes, and no radio-frequency modulator.

In preferred embodiments of its fourth major independent facet or aspect, the invention is a digital camera for plural-wavelength-band imaging with polarization information included; the camera includes an imaging sensor chip which is sensitive to optical radiation in at least two wavelength bands that substantially are mutually distinct, for recording an image. (This wording is selected to encompass wavelength bands that are mutually distinct in substance even though they may be slightly overlapping—as for example one wavelength band from 450 to 550 nm, and another from 530 to 630 nm.) The chip has a plurality of sensitive layers, each layer disposed substantially continuously across a field of view, and each layer is spectrally responsive respectively to a particular one of the at least two wavelength bands.

The sensitive layers for each of the bands, respectively, enable the sensor chip to discriminate spectrally among the bands of the radiation. The sensitive layers are stacked in series, so that incoming radiation in at least one of the at least two bands penetrates plural layers to reach a spectrally corresponding sensitive layer.

The camera also has a polarization mosaic overlaid on the stack of sensitive layers, also substantially continuously across the field of view. The mosaic defines an array of superpixels that impose polarization-state differentiation on the sensitive layers.

Also included in the camera is an electronic shutter to actuate the sensitive layers for exposure through the polarization mosaic for calibrated time periods, to acquire information for the image in the distinct wavebands with polarization information included. This camera has no means for vibrationally inducing diffractive fringes.

The foregoing may represent a description or definition of the fourth aspect or facet of the invention in its broadest or most general form. Even as couched in these broad terms, however, it can be seen that this facet of the invention importantly advances the art.

In particular, this facet of the invention represents a complete, functional, ready-to-go digital camera that records images in full color with polarization-state information included. As such it is a giant step forward in object-discrimination imaging. Further, while avoiding the use of so-called “vibro-fringes” (that may be delicate and sometimes temperamental, and can introduce oversensitivity to environmental conditions). This aspect of the invention provides simple and stable mechanics for acquiring extremely valuable data about multispectral and multipolarization-stage phenomena.

Although the fourth major aspect of the invention thus significantly advances the art, nevertheless to optimize enjoyment of its benefits preferably the invention is practiced in conjunction with certain additional features or characteristics. In particular, preferably the apparatus includes some means for displaying the acquired data (i. e., “display means”)—and in particular for successively presenting the image with different polarization-state information included. Through the operation of these means, image portions that include polarization states different from one another appear to flicker.

In another basic preference, the apparatus includes some means for trading-off resolution against frame rate (“trading-off means”), for acquisition of multiple sequential image data sets corresponding to a motion picture. The trading-off means in turn include some means for increasing resolution while decreasing frame rate, or conversely for increasing frame rate while decreasing resolution—to maintain generally constant total information acquired per unit time. Also included in this preference are some means for controlling frame acquisition rates of the acquisition means, in accordance with characteristics of the scene or of the acquisition process. Such “frame-controlling means” have been briefly discussed earlier. When the basic trading-off preference is observed, then a subpreference is that the at least two wavebands include at least three wavebands.

Still another basic preference is that the optical radiation be substantially incoherent radiation. In this case it is preferred that the sensor chip include means for recording all parts of the image mutually simultaneously.

If this preference for incoherent radiation is observed, then further preferably the substantially incoherent radiation is substantially exclusively ambient radiation. Here the first and second means collect all of the multispectral image and all of the polarization-state image through a single, common aperture—which as before does not include plural optical apertures in parallel but can have plural optical apertures in series.

In preferred embodiments of its fifth major independent facet or aspect, the invention is an image system. This apparatus includes some means for generating a temporal sequence of spatially registered multispectral, multipolarization images. For the previously mentioned reasons of generality and breadth, this document sometimes calls these means simply the “generating means”. The multispectral, multipolarization images each include multiple wavelength bands or colors, and plural polarization states.

The generating means operate using substantially only incoherent radiation. In addition the generating means include some means for discriminating among the wavelength bands or colors, and among the polarization states.

The generating means also include some means for temporally sampling at a sampling rate to form the sequence. The image system has no radio-frequency modulator.

The foregoing may represent a description or definition of the fifth aspect or facet of the invention in its broadest or most general form. Even as couched in these broad terms, however, it can be seen that this facet of the invention importantly advances the art.

In particular, the benefits of this facet of the invention are closely related to those discussed above for the third facet, which uses ambient radiation. Although ambient illumination is almost always exclusively incoherent, technically this is not strictly true always.

In addition this aspect of the invention extends most of the benefits of other aspects to situations calling for a temporal sequence of images, acquired at a particular rate of sampling, rather than a single image or isolated images; hence it is also in part related to the second aspect, which is peculiar to motion pictures and the like. This fifth aspect, however, in some ways is somewhat broader than the second aspect—in particular given that the rate is not necessarily keyed to characteristics of the scene or of an acquisition process, but may instead be selected on the basis of other considerations, e. g. specific experimental objectives. Accordingly this aspect of the invention is especially versatile.

In particular, in addressing the monumental importance of image sequences (but not necessarily motion pictures as such) this facet of the invention goes beyond the relatively basic acquisition of an image, in multispectral and multipolarization image space. As noted earlier, sequences can be used to invoke the human perceptual sensitivity to visual stimuli that are changing; even apart from that benefit, however, image sequences introduce at least two other fundamental capabilities as well.

One of these is the capability to record assemblages of objects from several different viewpoints, inherently interrelated as explicitly seen within the image sequence itself. Another is the capability to record historical development, over time, of phenomena represented in the image sequence.

Given these three functions peculiar to image sequences, it is especially important that this fifth facet of the invention includes means that address the need to establish a temporal sampling rate, by which a sequence can be formulated. Accordingly this aspect of the invention thus establishes both the fundamental capabilities enabled by an image sequence, and the related practical function of pacing the acquisition of such sequence. The prior art fails to come at all close to these functionalities, in multispectral and multipolarization imaging.

Although the fifth major aspect of the invention thus significantly advances the art, nevertheless to optimize enjoyment of its benefits preferably the invention is practiced in conjunction with certain additional features or characteristics. In particular, preferably the apparatus includes some means for modifying the sampling means (“modifying means”) to trade off spatial samples for temporal samples. The modifying means include means for increasing the number of spatial samples while decreasing the number of temporal samples, or increasing the number of temporal samples while decreasing the number of spatial samples, to maintain generally constant total information acquired per unit time. In particular the sampling means vary the sampling rate.

When this preference for introduction of “modifying means” is observed, then it is further preferable that the apparatus include operator-controlled means for setting the modifying means (e. g. “setting means”) to establish a desired sampling rate.

Other basic preferences, relative to the fifth main facet or aspect of the invention are that:
the generating means include some means for defining the temporal sequence as viewing at least one object from multiple viewpoints;
the generating means include some means for defining the temporal sequence as viewing historical development of a scene; or
the substantially incoherent radiation substantially is exclusively ambient radiation; and the generating means include some means for defining the temporal sequence as viewing historical development of a scene from multiple viewpoints.

In preferred embodiments of its sixth major independent facet or aspect, the invention is apparatus for multispectral and multipolarization imaging. The apparatus includes some means for acquiring data representing at least one multispectral image of a scene, including information that establishes polarization state at all or most points of the image. This document may call these means “data-acquiring means” or simply “acquiring means”.

The at least one multispectral image includes multiple different wavelengths or color bands; and the data include multiple data categories corresponding to the different wavelengths or color bands respectively. The data-acquiring means in turn include some means for discriminating among the data corresponding to the respective wavelengths or color bands, and also include a single optical aperture for passage of all optical rays used in formulating the multispectral-image and polarization-state data.

The foregoing may represent a description or definition of the sixth aspect or facet of the invention in its broadest or most general form. Even as couched in these broad terms, however, it can be seen that this facet of the invention importantly advances the art.

While related to the first five main facets of the invention, this sixth facet is very broadly addressed to multispectral, multipolarization data acquisition—discriminated by color band or wavelength band. That is, this facet is not at all specific to particular hardware. We believe that we are first to invent and describe any means for achieving such functions.

Although the sixth major aspect of the invention thus significantly advances the art, nevertheless to optimize enjoyment of its benefits preferably the invention is practiced in conjunction with certain additional features or characteristics. Preferably the data-acquiring means operate using substantially only incoherent ambient radiation; and include means for recording all parts of the image, including the polarization information, mutually simultaneously.

The foregoing features and benefits of the invention will be more fully appreciated from the following detailed description of preferred embodiments—with reference to the appended drawings, of which:

### BRIEF DESCRIPTION OF THE DRAWINGS

FIG. 1 is a pair of photographic images of a land scene for comparison—the A (left-hand) view being the polarized return and the B (right-hand) view unpolarized;

FIG. 2 is an elevational drawing (after Barter et al.⁸), rather schematic, of a known entrance-optics system for separating several different-image planes by means of a spectrally neutral beamsplitter prism—and relatively aligning them for best registration;

FIG. 3 is an isometric or perspective view (id.) of a four-channel prism used to produce the FIG. 2 separations;

FIG. 4 is a plan (after Sadjadi et al.⁹), very schematic, of a micropolarizer array or so-called “polarization mask”, matched to pixels of a photodetector array;

FIG. 5 is an elevational cross-section (id.), highly schematic, showing a wire-grid polarizer that is one type of mask such as shown in FIG. 4, bonded to a common substrate with the matched photodetector assumed in FIG. 4;

FIG. 6 is a set of three views (after Millerd et al.¹⁰) showing alternative fabrication technologies for micropolarizer arrays—the A (left-hand) view being a plan of one unit of the FIG. 4 mask, but with a different assignment of polarization-direction positions; the B (center) view being an isometric of perspective view of a single-layer array; and the C (right-hand) view being a like view but for a multilayer array;

FIG. 7 is a pair of photomicrographs (after Gou et al. ¹¹) of two-dimensional micropolarizer arrays prepared from polarizing thin films—the array in the A (left-hand) view having 5 μm pitch, and that in the B (right-hand) view being an integrated micropolarizer/CMOS imaging array at 14 μm pitch;

FIG. 8 is a photograph of the OVP Opus 1 camera;

FIG. 9 is a group of five diagrams, somewhat schematic and some shown partially broken away, of the Foveon sensor-array chip together with its operating light-absorption principle;

FIG. 10 is a like group of diagrams of a more-traditional multispectral sensor-array chip and corresponding light-absorption principle;

FIG. 11 is a system block diagram, highly schematic, of one preferred embodiment of a multispectral, multipolarization camera that includes a polarization mosaic aligned with a single multispectral imaging array;

FIG. 12 is a like diagram of another such embodiment that instead includes an image-splitter prism with multiple multispectral imaging arrays;

FIG. 13 is a cross-sectional diagram (after Silicon Imaging, currently seen at www.siliconimaging.com/RGB%20Bayer.htm), somewhat schematic, showing conventional integration of a three-unit cell of a microlens array into a Bayer CMOS sensor array;

FIG. 14 is a group of four images of a single common scene, representing in the upper-left “A” view a full-frame photo taken in horizontally polarized panchromatic (or monochromatic) light; in the upper-right “B” view a like photo in vertically polarized light; in the center-right “C” view a like photo but of only a selected region of interest (“ROI”); and in the bottom “D” view a hybrid photo of the same ROI but generated from the difference between vertically and horizontally polarized light, displayed in red—but with an overlaid copy of the vertically or horizontally polarized version, displayed in a light blue for positional reference only;

FIG. 15 is a partial block diagram representing a front-end portion of FIG. 11, but expanded to include several optical refinements—incorporated preferably as a single-piece composite assembly, together with the polarization mosaic, at the front end of the optical system—namely a diffuser, microlens array, and auxiliary spectral filters;

FIG. 16 is a system diagram, highly schematic, showing scene-image acquisition at a frame rate suited to the dynamics of acquisition, but scene-image display at a frame rate suited to the processes of human visual capability;

FIG. 17 is a timing diagram showing opposed-polarization or sequential-polarization flicker display, extracted (according to the present invention) from a multispectral, multipolarization image;

FIG. 18 is a group of five images of a single common scene, very roughly simulating the process of radiometric balancing in preparation for such flicker display: the “A” and “B” views at left and right center represent “raw”-data images taken in horizontally and vertically polarized light; the “C” view at top likewise simulates the difference (with very greatly increased contrast) between illumination levels in the “A” and “B” views, and hence represents the flicker display when the “A” and “B” views are displayed in alternation; the “D” view at lower right is a copy of the “B” image adjusted for overall radiometric balance with the “A” image; and the “E” view at bottom is the difference (with contrast increased exactly as in the C″ view) between the “A” and “D” views—and hence simulates the flicker display when the “A” and “C” views are displayed in alternation; and

FIG. 19 is a pair of still frames extracted from a video, after Yemelyanov²⁵, illustrating one form of periodic polarization-signature counterfading “flicker” display—the upper, “A” view being a frame selected at the beginning of a cycle, and the lower, “B” view being selected roughly at the center of the cycle (i. e. phase very roughly 180 degrees).

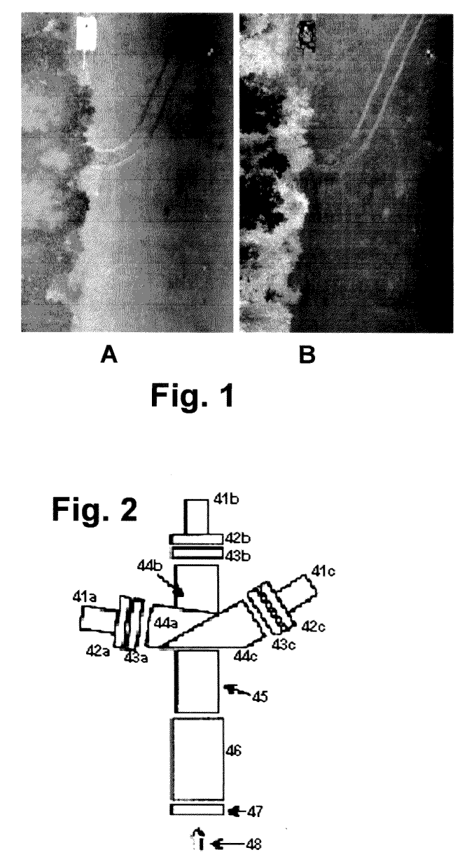

### DETAILED DESCRIPTION OF PREFERRED EMBODIMENTS

Preferred embodiments of the invention integrate and optimize multispectral- and multipolarization-array systems into a single compact digital camera that is uniquely effective in detecting and identifying objects in complex environments. This new system essentially eliminates the previously described impediments to consistently superior object discrimination.

The unit is also low in weight, low in power consumption, and very reliable. Furthermore it is particularly convenient in use, as it is ready for connection to an ordinary computer through a conventional USB 2.0 interface.

Unlike the separate—but bulky and somewhat heavy—systems introduced earlier, the present invention occupies less than eight cubic inches and weighs less than one pound. More importantly, the multispectral/multipolarization (MS/MP) camera inherently yields data substantially free of registration error, and thereby delivers significantly enhanced surveillance capabilities for small UAVs as well as the several other applications mentioned earlier.

For military personnel in the field, this is exactly the kind of advanced real-time, optimum-quality surveillance and reconnaissance capability that has been severely lacking in all prior apparatus. The integrated MS/MP camera is equally suitable for insertion into existing UAV-based passive mine-detection systems; and entirely revolutionizes the commercial applications discussed above.

At a price under $20,000, this self-contained device is within the budget of medical-diagnostic, industrial-process, industrial process control, and land-use organizations. A comparison of various multispectral, multipolarization imaging approaches appears listed in Table 3, below. As

TABLE 3
comparison of the invention and prior art

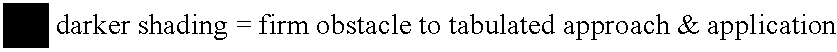

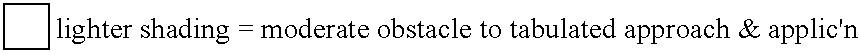

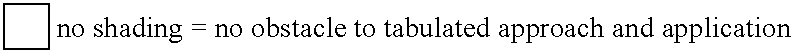

| | | | | channel | | |
|---|---|---|---|---|---|---|
| imaging | diversity (bands) | | | regis- | small | |
| approach | spec. | pol. | view | tration | UAV | comments |
| spinningfilter wheel | ~5(spectral/pol.) | | | | 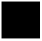 | subpixel regis-tr'n difficult |
| multiplecameras | ~4 to 9(spectral/pol.) | | | | 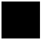 | requires verycareful alignment |
| multipleCCD | 3 spectralbands or 3 pol. | | | | | registr'n re-quires postproc'g |
| hyperspectral(pushbroom) | ~128 | 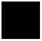 | 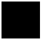 | | 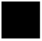 | no view or pola-riz'n diversity |
| multichipspec/polar'n | 3 | 4 | | | | registr'n re-quires postproc'g |
| 1-chip | 3 | 4 | | | | single chip en- |
| spec/polar'n | | | | | | sures registr'n |

the table makes clear, a single-chip MS/MP camera overcomes deficiencies in previous approaches and paves the way for exploitation of the MS/MP imaging—not only tactically from a small UAV but also in civilian applications of potentially far greater societal value.

Realization of the discrimination capability provided by these multidimensional imaging systems is dependent upon precise spatial and temporal registration of the different spectral/polarization bands. The ideal solution, provided by the present invention, is a single camera that can simultaneously provide images that are both multispectral and multipolarization, from a single chip in a single exposure. As this last-mentioned condition implies, all spectral and polarization image planes are inherently registered; hence there is no registration error.

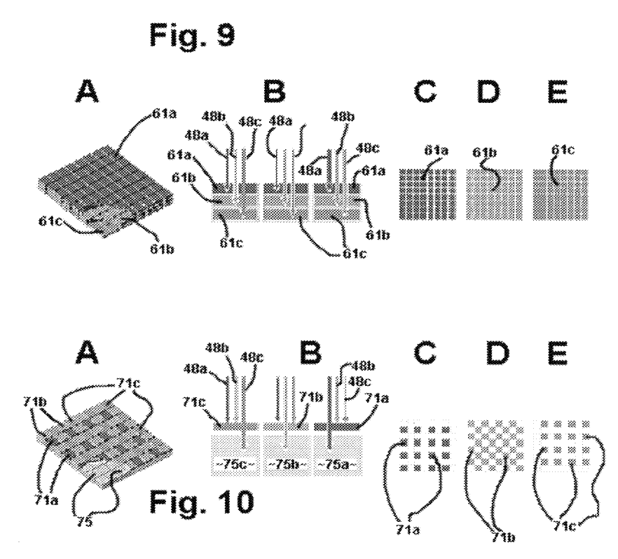

Preferred embodiments of the invention use the previously described Foveon X3 single-chip direct imaging sensor¹² (FIG. 9). This CMOS device provides high resolution (10 megapixels: 2268×1512×3 bands), large dynamic range (12 bits), and wide spectral bandwidth (350 to 1110 nm), and is now available in an integrated camera system¹³ (FIG. 8, Table 2), complete with USB 2.0 interface. This multispectral camera system completely eliminates the spatial registration and aliasing problems encountered with more-familiar multiCCD and Bayer-type color cameras.

Preferred embodiments of the invention expand the spectral-imaging capability of the Foveon X3 chip and OVP Opus 1 camera to incorporate polarization-state sensing as well. From a user/operator perspective, the integration of this additional capability is essentially seamless. That is to say, operation of the hybrid device at the point of capturing an image involves—once the several imaging parameters have been set for an exposure—simply actuating one electronic “shutter” control.

Preferred embodiments primarily encompass two alternative techniques, both mentioned in an earlier section of this document, for acquiring polarization-diversity information. One of these uses an achromatic polarization beamsplitter and multiple imaging arrays; the other uses a micropolarizer array (polarization mask) coupled to a single imaging array.

Both have been successfully used in the past to provide polarization discrimination for panchromatic imaging sensors. Neither, however, has ever been previously integrated with multispectral sensors as provided by preferred embodiments of the present invention.

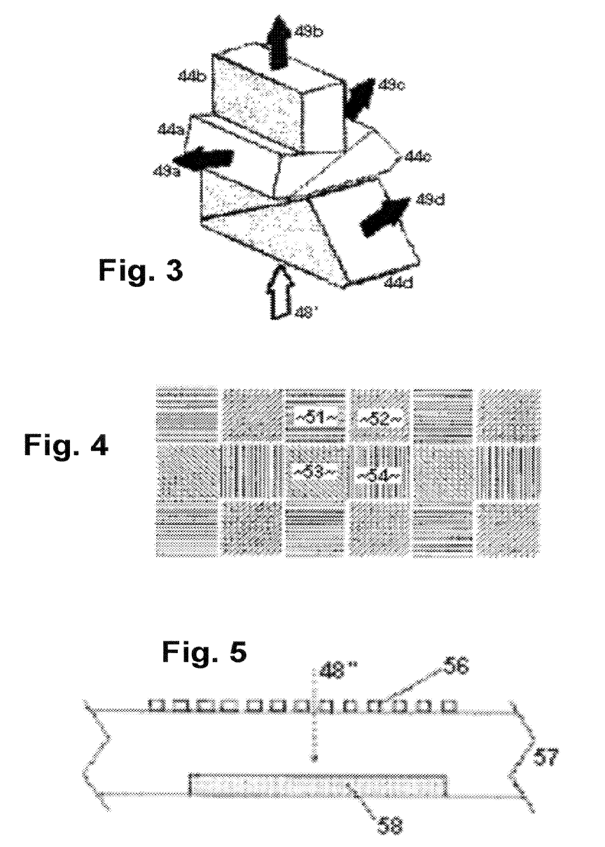

The polarizing-beamsplitter approach uses a spectrally neutral splitter prism to separate an incoming image into multiple image planes, each of which is then coupled to a corresponding separate imaging array (FIG. 3). These splitter prisms, common in multichip color cameras, have been successfully used for panchromatic polarization imaging¹⁴.

As noted earlier a system of, for example, dichroic splitters can be substituted for a prismatic one. Some mitigation of the cost, weight and inconvenience of the prismatic splitter may be achieved in this way.

By directing each of the separate image planes to a corresponding separate Foveon X3 image sensor for detection and processing, our invention straightforwardly achieves multispectral/multipolarization imaging. Although this form of the invention is operable, we prefer the alternative (polarization mask) architecture, which is considerably less complex, expensive, heavy, and awkward—particularly as to registration.

This single-chip approach (a polarizer array with a single multispectral imager) is more capable and robust, particularly for applications that require very precise spatial registration of the multiple spectral/polarization images in a small and compact configuration. Integration of the polarizer array to the existing Foveon chip is relatively straightforward, and as noted earlier the OVP Opus I camera provides a convenient USB-2.0 interface.

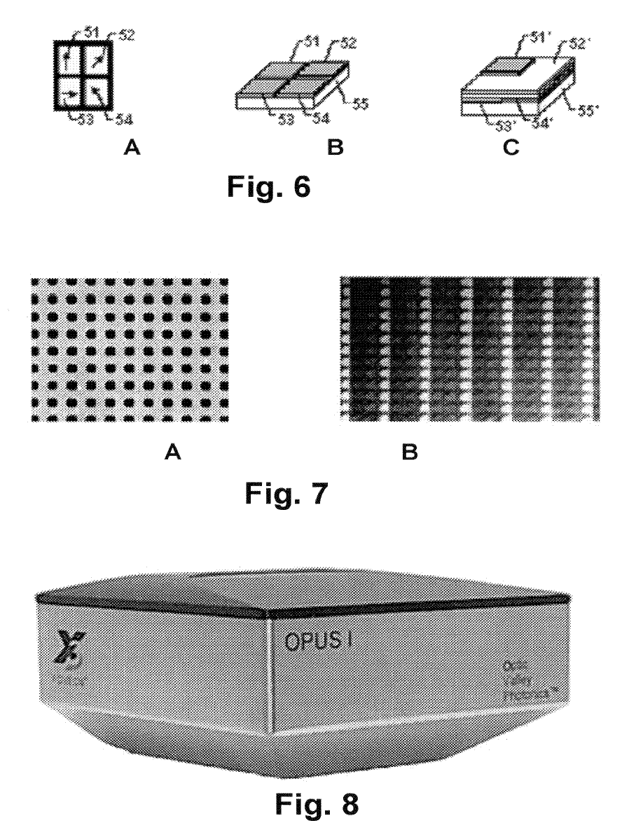

Polarization masks for multipolarization imaging have been successfully demonstrated in the infrared¹⁵, and recent advances in fabrication technology have extended the capability to manufacture micropolarizer arrays for the visible regime¹⁶. A basic component is a custom-built two-dimensional array of micropolarizers (FIGS. 4 and 6B) that is precisely registered and bonded to an underlying imaging array.

Advantageously the polarizer array inherently can be made generally planar—unlike the multiple separate image planes from the polarization beamsplitter (FIG. 3) discussed above—and hence is particularly amenable to coupling with a single, composite multiplane detector such as the X3.

A two-by-two “unit cell” of linear polarizers 51, 52, 53, 54, (FIGS. 4 and 6B) with polarization directions respectively at 0°, 45°, 90° and 135°, is stepped both column-wise and row-wise across the entire imaging array. Each pixel of the underlying array thus measures a single linear polarization state in each of three spectral bands. In this way the group of sensor pixels, or “superpixel”, underlying each 2×2 unit cell measures each of the four linear polarization states at each of three spectral bands.

The “Background” section of this document outlines the two techniques currently used to fabricate suitable polarization masks. They are a wire-grid-array process (single layer, FIGS. 4, 5 and 6B), and a multilayer thin film approach (FIGS. 6C, 7A and 7B).

As there noted, wire-grid arrays have been successfully fabricated to 9 μm pixel pitch, in array sizes exceeding 1000×1000 pixels¹⁷. Adapting these fabrication processes to the 9.12 μm pixel pitch and 2268×1152 pixel format of the Foveon X3 chip—although not done heretofore—is straightforward.

The invention contemplates further trial-and-error refinements to mitigate the previously mentioned degradation of polarization contrast at short visible wavelengths. One such improvement in particular appears to lie in reported successful fabrication of wire grid arrays 56 (FIG. 5) with spacing as close as 100 nm¹⁸, bonded to an intermediary substrate 57 and sensor array 58.

The alternative micropolarizer devices for the visible spectrum have been successfully fabricated using polarizing thin films 51′ to 54′ (FIG. 6C) in a multilayer configuration, and such arrays have been successfully bonded to CMOS arrays¹⁹ 55′. The original device was based on a 13.8 μm×14.4 μm pixel pitch and formed as a 352×288 pixel array.

In addition, polarization masks made of multilayer thin film were constructed to a pixel pitch as fine as 5 μm. Adaptation of this demonstrated fabrication technology to a 9.12 μm pitch, 2268×1512 array is also straightforward—since the spacing is typically established by simply drawing or enlarging a photolithography mask to the desired dimensions. Integration of the polarization mask (whether wire grid or multilayer) with the Foveon X3 chip is likewise straightforward.

As to the latter, preferred embodiments of our invention follow process and alignment techniques developed by 4D Technologies for that firm's interferometer product lines—see U.S. Pat. No. 6,304,330 or its divisional U.S. Pat. No. 6,552,808, hereby wholly incorporated herein. Those techniques are readily applied to the larger Foveon array.

Performance of the integrated multispectral-multipolarization camera of our invention follows that of the Foveon/OVP Opus I camera (Table 2). While the Foveon direct-imaging sensor and readout technology supports a 4 Hz frame rate, bandwidth limitations of the USB 2.0 standard restrict readout to a range between 1 and 2 Hz. Our invention contemplates data compression to exploit the full 4 Hz image rate via the USB interface; alternatively, with a higher-bandwidth interface this technology can provide higher frame rate directly.

Application to UAV-based surveillance—The Opus I camera uses a standard C-mount, and is fully compatible with standard 35 mm commercial off-the-shelf (“COTS”) lenses. Adapters are available for other lens formats.

The standard USB 2.0 data interface has true plug-and-play capability with standard PCs. In the commercial Opus I camera, power is supplied through a separate power adapter (6 Vdc at 5 W); however, our invention contemplates managing the camera power for provision directly through the USB interface. Overall weight of the MS/MP camera with lens, using the standard Opus I case, is between one and two pounds, depending on lens aperture and focal length.

For custom integration, the board set can be reconfigured by conventional design techniques to a different form factor. The bare camera board set weighs only 0.15 pound.

Our invention contemplates, through lightening of the case and input optics, a complete MS/MP camera weighing less than one pound, with a total volume of 8 in.³ or less. This camera will enable an extremely robust MS/MP surveillance capability for a broad class of microUAVs and other valuable applications mentioned earlier.

Our high-resolution integrated MS/MP digital camera, according to preferred embodiments of the invention, yields a wholly new observation capability. Multispectral/multipolarization imaging provides significantly enhanced discrimination capability to detect objects of interest in heavy clutter—and thus effectiveness in medical, ecological, industrial and military applications. Its low cost and high performance enable widespread use.

Development suggestions—For successful practice of this invention, a key initial step is careful design and characterization of a polarization mosaic (analogous to e. g. FIG. 4) suitable for direct integration with the existing Foveon X3 chip and OVP Opus I camera with USB interface. Study of critical process issues, quantitative estimates of MS/MP camera performance, and laying out a path for camera fabrication and integration will avoid delay.

At this point it is advisable to optimize design of the polarization selection approach—as among wire-grid array (FIG. 5), multilayer array (FIG. 6C), and neutral-splitter prism (FIG. 3)—including characterization of spectral performance (polarization contrast versus wavelength) of existing 9 μm pitch wire grid arrays. Also included should be design and modeling of performance for a 9.12 μm pitch multilayer polarization array (FIG. 6C)—and then complete system design and performance modeling of the integrated MS/MP camera, based on optimal polarization alternatives.

A later pivotal step, after verifying performance to the intended specifications, is development of algorithms to exploit the multidimensional data, and perform data acquisition—in particular airborne data collections using the integrated camera, assuming that such applications are of particular interest. That step should thereby demonstrate the capability to perform robust target detection and identification from an airborne platform. The integrated camera and discrimination algorithms should then be available for immediate transition to production-engineering of, for example, UAV integration.

In this regard, even though the present invention minimizes the need for extremely intensive postprocessing, it is also essential to look forward toward development of ground-station systems (hardware and software) to perform such advanced interpretive postprocessing as may nevertheless be desirable. For maximum utility, such calculations should be done in as nearly real-time as possible.

This invention is believed to be particularly valuable in the scientific-imaging marketplace. We estimate the market for these high-end scientific-grade camera systems with integrated multipolarization capability to be on the order of one hundred to three hundred per year. The wider commercial market, including the medical-monitoring and other applications mentioned earlier, is expected to develop as new applications emerge from these enabling technologies.

Additional refinements—The integrated multispectral-multipolarization camera has several attributes that overcome deficiencies in alternative approaches:

1. Use of a single aperture avoids distortion and alignment problems suffered by multiple aperture approaches.

2. A single exposure ensures precise temporal simultaneity of data, avoiding temporal aliasing due e. g. to spinning filter-wheel approaches.

3. Precise spatial registration of image bands and polarization states avoids spatial aliasing of images from multiple-camera approaches, and multiple exposures from a moving or vibrating platform.

4. An extremely compact and rugged design suits the system to harsh environments such as high-acceleration, high-vibration reconnaissance vehicles, shuttle and other spaceflight applications—and also many industrial and clinical uses with minimal constraint on operator procedures.

Many scenes can have very large dynamic range between alternate spectral bands or polarization states, or both. Exploitation of the MS/MP attributes of the scene is compromised if there is spatial aliasing, temporal aliasing, and/or “bleed through” of one polarization state to another. Our MS/MP approach overcomes these deficiencies of alternate approaches by using a single aperture, single exposure, and precise spatial registration.

Spatial registration is critical in optimal exploitation of MS/MP data, and each spectral and/or polarization image has to be precisely registered to each of the other bands. In this context, the requirement for precise registration is driven by the information content in each of the spectral bands, and the degradation in image content should the data be spatially or temporally aliased.

Polarization purity between channels (i. e., extinction ratio) is exceptionally critical. For images taken from a moving aircraft or vibrating vehicle, band-to-band spatial registration must be a small fraction of a pixel, preferably much less than 0.1 pixel, and in any event much smaller than the spatial scale of significant changes in the spectral/polarization content as the platform moves over the scene.

Similarly, images of a dynamic scene (i. e. moving ocean waves, leaves moving in wind, etc.) suffer from temporal aliasing if the scene changes between exposures. In this case, images need to be temporally simultaneous, preferably to 1 msec and less.

These requirements for spatial and temporal registration are difficult if not impossible with conventional approaches, yet readily overcome with the present invention. Such spatial and temporal registration is readily accomplished in either of our two MS/MP implementations.

REFINEMENTS, USING A POLARIZATION MOSAIC—For the polarization-mosaic approach, temporal simultaneity is inherent in the use of a single chip with a single exposure for all spectral and polarization images. High-fidelity polarization images (large extinction ratio) require precise alignment between the polarization mosaic and the image array.

Such alignment is preferably accomplished by interferometric techniques, as described by J. Millerd et al. in “Pixelated phase-mask dynamic interferometer” (SPIE 2004). In this technique, alignment between the phase mask and camera is optimized by using the camera in a Twyman-Green interferometer.

The polarization mask is adjusted to maximize the fringe contrast of the resulting interferogram. Spatial alignment of the polarization mosaic to the underlying image array has been demonstrated to much less than 0.1 pixel using this technique.

REFINEMENTS, USING SEPARATED IMAGING—For the approaches using an image-splitter prism and/or multiple-image-array, temporal simultaneity is accomplished by triggering the image capture from a common time base. Spatial registration of the multiple image arrays may also be accomplished using interferometric techniques, which are far superior to the image-differencing techniques used by alternate approaches (Barter et al.).

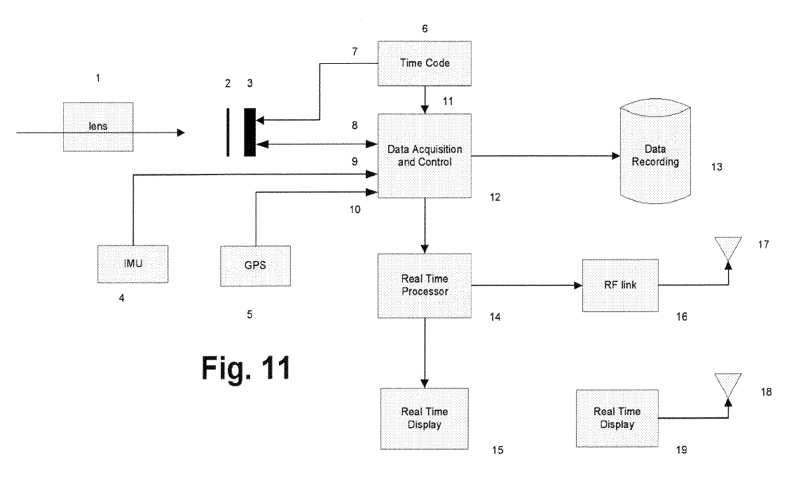

REFINEMENTS, USING INTEGRATED FABRICATION—Yet a third approach of assuring spatial registration and temporal simultaneity is to use advanced microlithography fabrication technologies to incorporate the microgrid polarization mosaic 2 (FIGS. 11 and 15) onto the image array. The integration of polarization discrimination is thus accomplished as part of the fabrication process for the imager.

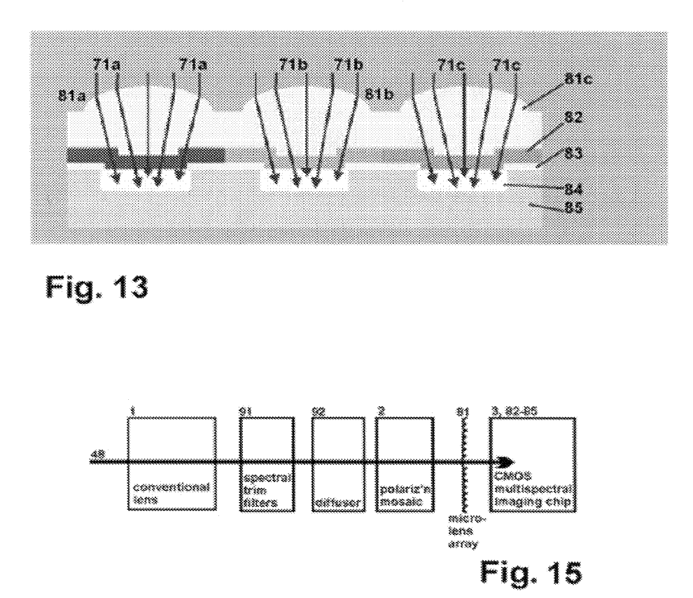

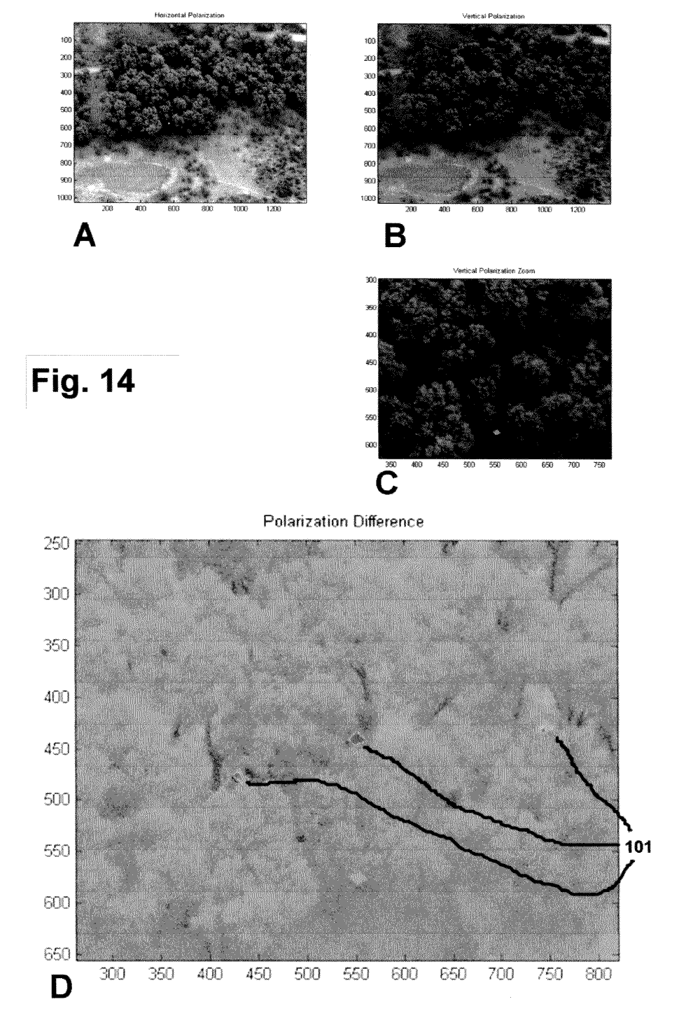

REFINEMENTS, USING LENSLET ARRAYS TO CORRECT FILL FACTOR—As noted in the “BACKGROUND” section of this document, it is known to correct light-blocking internal geometry (“fill factor”) of Bayer-type displays through integration of a microlens array 81a-b-c (FIG. 13). According to preferred embodiments of the present invention, an analogous condition in foveal sensor arrays such as the Foveon X3 can be addressed by use of an analogous microlens array 81, typically integrated with the rest of the assembly (FIG. 15), to enhance radiometric efficiency of the multispectral, multipolarization imaging sensors of the present invention.

REFINEMENTS, USING DIFFUSERS TO CORRECT POLARIZATION-MOSAIC ALIASING—In certain situations where polarization properties vary on spatial scales close to the spatial Nyquist parameter of the imaging array, polarization data using the polarization-mosaic approach may suffer from spatial aliasing. (Such aliasing appears to be less severe for the approach using a polarization beam splitter, which may be the preferred embodiment in geometries having aggravated aliasing.) To mitigate such aliasing, a diffuser 92 may be included so that the incoming radiation is blurred across each two-by-two-pixel polarization superpixel.

This provision ensures that within each superpixel all four polarization elements receive radiation from substantially the same position in object space. Such a diffuser, too, may be integrated with the polarization mosaic, microlens array etc. to form an integrated, monolithic filter array.

REFINEMENTS, USING COLOR FILTERS TO OPTIMIZE SPECTRAL RESPONSE BY SCENE—The optimal spectral bands for object detection and discrimination are often scene dependent. Techniques have been developed to define the optimal spectral bands depending on the characteristics of the objects of interest and the background scene. These techniques are now publicly available to workers of ordinary skill in this field.²⁰

Conversely, the spectral characteristics of the imaging arrays are often determined by the physical properties of the materials, and the thicknesses of the various material layers. This information too is of course available as part of the published specifications of each imaging device.

Optimizing spectral response at the device level (i. e., in the imaging array itself) is typically very expensive and time consuming. The effective response of the imaging array may be modified, however, by integrating one or several spectral filters 91 in front of the array. Such filters, in turn, may be integrated into the monolithic assemblies mentioned just above, to further enhance the multispectral/polarization imaging. As will be understood, the order of these several elements is subject to some variation.

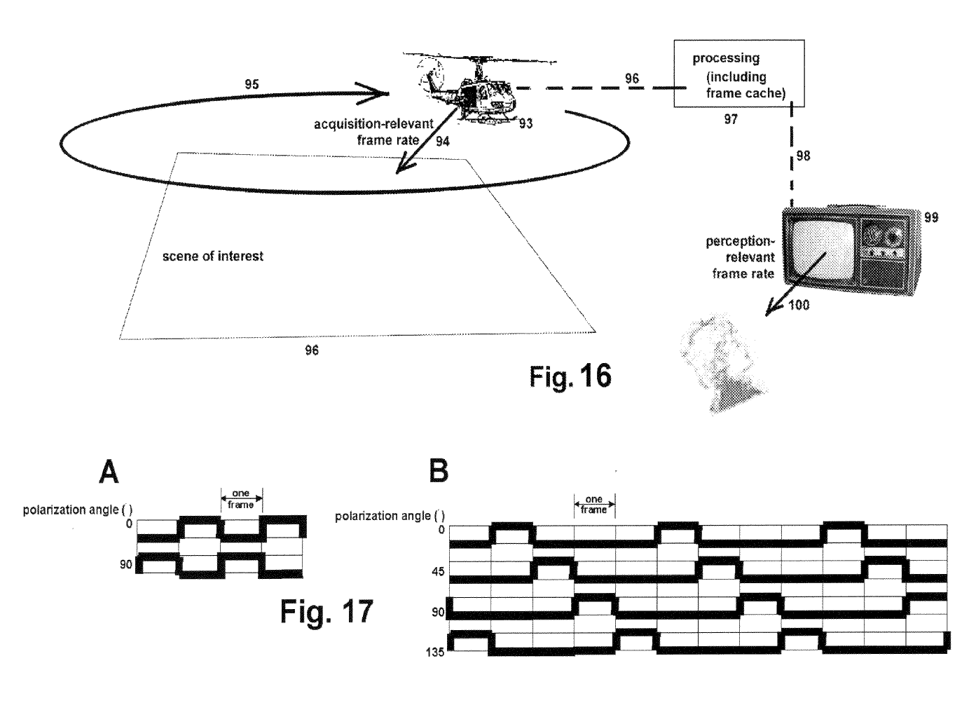

REFINEMENTS, USING MOTION PICTURES AND POLARIZATION-STATE FLICKER—For imaging from a rapidly moving platform 93 (FIG. 16) that may execute complex movements about a scene 96 of interest, and/or imaging of a dynamic scene (moving objects), rapid temporal sampling 94 is required to fully exploit the advantages of multispectral-multipolarization imaging. For optimal performance, the temporal sampling should be at least twice the highest frequency component of interest in apparent motion of the scene (Nyquist criterion).

Similarly, the spatial sampling should be twice as fine as the smallest spatial feature in the image. Depending on the application, one may need more spatial pixels at relatively coarse temporal sampling (relatively static scenes), or conversely, rapid temporal sampling at coarse spatial resolution (highly dynamic scenes).

An imaging system that can optimally trade off spatial and temporal sampling will find the widest utility across the broadest range of applications. Our invention advantageously promotes this goal.

The tradeoff between spatial and temporal sampling can be accomplished in a number of ways. These include manual setting, automatic but static setting, and dynamic setting of the sampling parameters.

Ideally the acquisition process 94 has some computing capability for preliminary setting of the tradeoff, and thereby selection of the acquisition frame rate, to facilitate best results in the later stages 96-100. In any event the acquired image information 96 passes to a processing module 97 that may be located with the acquisition platform 93 or the display apparatus 99, or located distributively with both—or may be elsewhere entirely—and the processed data 98 proceed to the display system.

The electronics at any of these locations 93, 97, 99 may be designed to “bin” pixels (sum the charge from adjacent pixels), sparsely sample the pixels across the image plane, and/or interrogate pixels from only a small area of the image plane (“region of interest”, ROI).

Techniques that can allocate pixel density dynamically to regions with the highest spatial frequency content (“foveal vision”) record the maximum scene content with the minimum number of spatial—i. e. hardware—pixels. Each of these techniques reduces the effective number of spatial pixels, and allows an increased temporal sampling rate.

Ideally all or most of such dynamic-allocation apparatus is on-board the acquisition platform 93. Generally the acquisition frame rate 94 is related to the dynamics of the acquisition process, whereas the display frame rate 100 should be decoupled from the acquisition rate and instead conditioned on the human perceptual processes. Among other necessary equipment, to effectuate this scheme, is likely to be a frame cache.

Such methods allow for dynamic optimization of the spatial/temporal sampling for the widest variety of MS/MP applications. These methods too are within the sweep of the present invention.

The information content of the MS/MP data is optimally displayed using computer-based signal processing algorithms to automatically enhance those signature attributes characteristic of objects of interest, while simultaneously suppressing background clutter. Such techniques are known for multispectral data²¹ and according to this invention are extensible to multipolarization data.

As mentioned earlier, polarization-difference display as known in the prior art has several limitations. These include the desirability of a false-color separation between the difference signatures and a positional overlay, and the incompatibility of such false-color technique with multispectral imaging if the image region which is so-treated is large.

They also include the uncontrollable relationship between polarizing-surface orientations in the scene and polarization states used to generate an image. Although difference display can nevertheless be used in some embodiments of the present invention, more highly preferred embodiments instead rely upon a flicker system as described below.

To exploit the cognitive power of human perception, image data from alternate spectral or polarization bands, or both—or combinations of selected such bands—may be displayed in alternation (FIG. 17A), at a modest frame rate (a fraction of a hertz to a few hertz) to provide the observer with visual cues to the subtle differences in spectral and/or polarization content. Such “flicker” imaging can provide a powerful way to identify objects of interest in a high clutter environment.

Simple alternation of, e. g., vertically and horizontally polarized frames (FIG. 17A) is distinctly preferable to difference display, as the alternation technique minimizes the need for false color. Such rendering should not be necessary outside the polarization-difference (“PD”) regions, and typically for discrimination of partly concealed objects in otherwise-natural scenes these PD areas are small.

This technique thereby minimizes the intrusion of such artificial mechanisms into the natural color of a multispectral scene. Nonetheless such vertical/horizontal alternation can be troublesome for the reasons mentioned earlier in conjunction with difference display—namely, the generally unknown relationship between polarization parameters in the scene and polarization states used to capture the image.

Some of the previously mentioned display techniques of Yemelyanov serve well for the visualization needs of the present invention. This is particularly true of his flicker methods, and particularly if constrained to PD regions.

A variant alternation method, also within the scope of the present invention, is to collect polarization data for more than two states, and preprocess the image data automatically to determine the best crossed polarization states for flicker display. The selected states may be either the best of the states actually used in data acquisition, or intermediate states—with interpolation applied to generate light levels not actually measured. Within limits this technique can be applied independently for each scene element that has any detectable flicker component.

A most highly preferred embodiment, however, instead displays a sequence of light levels for four polarization states (FIG. 17B). In this method the polarization-difference flicker signature is most pronounced, in amplitude, if polarizing axes in the scene happen to be aligned with polarization states used in acquiring the image.

The high-amplitude phase is associated with one frame out of the four frames that make up an entire cycle of the display sequence. A low-amplitude phase occurs in one other frame of the four, at an opposite point in the cycle.

The flicker signature is least pronounced, in amplitude, for polarizing axes in the scene that happen to be at forty-five degrees to polarization states used in acquiring the image. In compensation, however, this lower-amplitude flicker signature tends to be protracted.

That is, the high light level (though it is not very high) covers two quadrants (two frames of four) of the overall flicker waveform rather than only one. Hence the visual perception of the return is not as low as might be expected from considering the amplitude alone.

Analogous tradeoffs of amplitude and duration occur for all other angles (of scene polarization axes to one of the illumination axes)—i. e., angles intermediate between zero and forty-five degrees. Consequently this embodiment of the invention yields a very noticeable and satisfactory flicker signature, regardless of polarization orientations.

This is true even though the flicker signature is perceptibly different for different orientations. In fact a very skilled operator can read, so to speak, the visible behavior (amplitude and temporal quality) of the flicker signature to discern likely orientations of manmade surfaces in the scene.

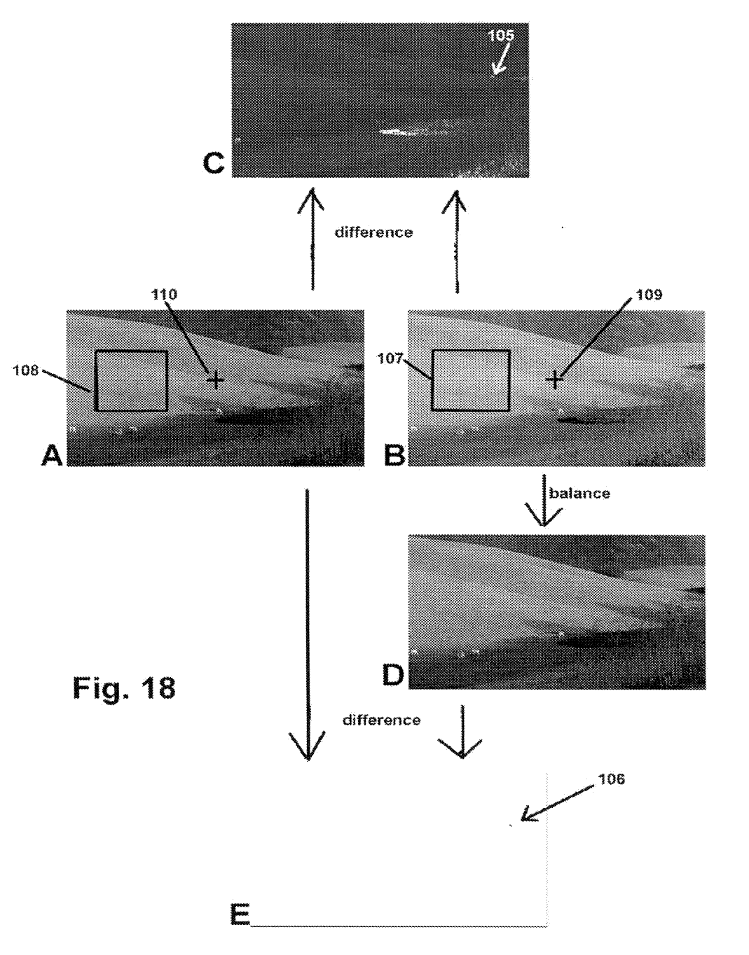

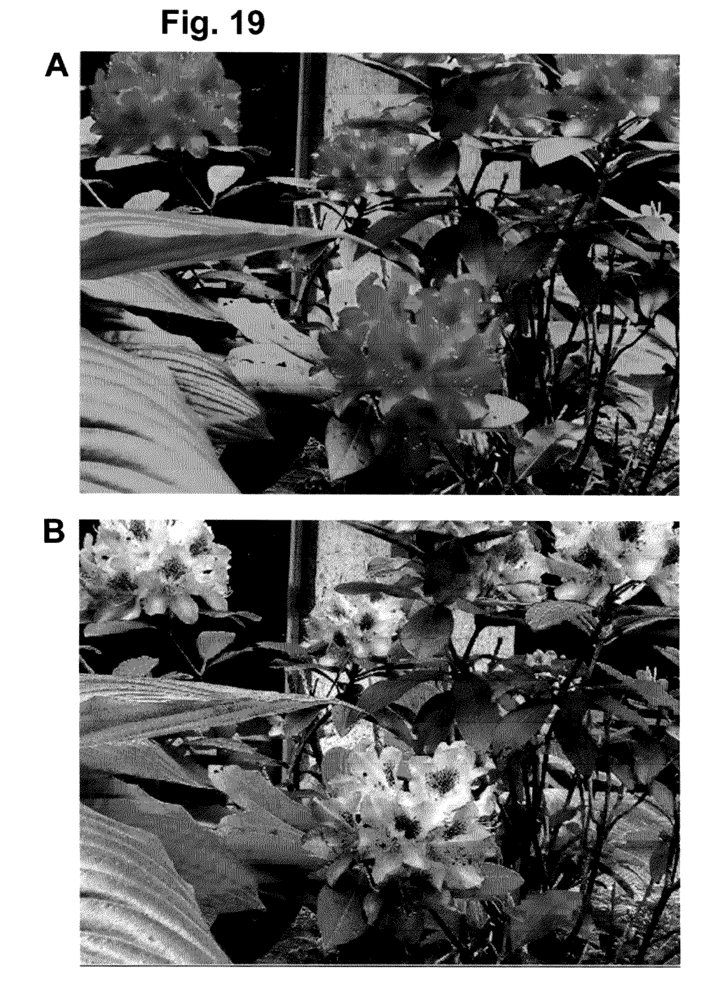

In many such adaptations of our invention it is particularly advantageous to preprocess the data so as to provide good radiometric balance as between the native exposures (FIGS. 18A, 18B) taken at the various diverse polarization states. This precaution avoids distracting or confusing the observer with underlying exposure variations that might be taken as polarization-state modulations.

The basic idea behind this technique is this: most natural ambient scene features, such as foliage (except for broad-leafed, waxy plants) and dry soil, do not appear significantly polarized—and therefore should appear roughly the same when viewed by differently polarized return. In such an observational mode any significant difference (FIG. 18C) between the raw-data returns (FIGS. 18A and 18B), for most natural features, is therefore most likely an artifact of the observational process. In a flicker display related to such difference data (FIG. 18C simulation), the entire scene appears to flicker very strongly.

Even though the polarization signature 105 may appear quite clearly, it may be rendered very inconspicuous by such strong flickering of a complicated-looking scene-wide artifact due to poor radiometric balance. Since that artifact nearly swamps out the flickering polarization signature 105, in perceptual terms, the method may fail to effectively discriminate objects from background.

The overall apparent level for one or more of the polarization states (FIGS. 18A, 18B) can therefore be respectively raised or lowered (e. g. from FIG. 18B to FIG. 18D), or both, to force the appearance of the natural features to be substantially the same for all of the polarization states. (This step may be called balancing, or normalization, or equalization.) The previously introduced work of Yemelyanov et al. includes such balancing, indeed a particularly cautious form of it—histogram balancing—that equalizes the background tonal-band by tonal-band, and thus tends to minimize occurrence of ghost artifacts in some tonal ranges.

Any scene features 106 (FIG. 18E) that really are significantly polarized will continue to exhibit light-level differences and therefore a clear flicker amplitude, and these should stand out very prominently against the normalized natural background. In this very rough illustrated simulation of flicker display, the alternation of the two backgrounds generates no visible flicker at all, since the two backgrounds have been rendered substantially identical.

Simulated as a difference frame, the background flicker here appears black—or white when inverted (FIG. 18E). It should be borne in mind that the scene images to be alternated are not monochrome as in this very rough simulation but rather are full color; yet the polarization signature shows up clearly in the flicker display.

The preliminary normalization process can be performed automatically, or semiautomatically, by preprogramming which first enables a human operator to very quickly select the entire image frames for averaging and balancing, or select matching bounding boxes 107, 108, or select matching target points 109, 110, that are not expected to be inherently polarized. The program then follows-up on the operator's selections by making the above-described adjustments in level.

In most scenes, unpolarized natural features (or natural features whose polarization return is so mixed as to appear very weakly polarized) in fact occupy the great bulk of the image area; hence alternatively an initial default selection (e. g., entire frame), of an area for use in balancing, can be made without operator input. An operator, however, can then check the scene—either before or after the equalizing of the levels and the viewing of the flicker display—to weed out occasional evidently inappropriate details of the selection.

Data obtained through use of our invention (especially but not necessarily if acquired by binning or ROI techniques, mentioned above) can then in turn be displayed in a way that takes advantage of the ability of human visual perception to integrate images received in rapid succession. (The successive images discussed here are apart from the flicker display discussed above.)

Ideally such successive views are acquired at or near the conventional frame rates for commercial motion pictures and video, or preferably are instead later processed to be at those rates, so that the succession of images later can be displayed using wholly conventional motion-picture or television display equipment.

In most cases it is ideal to acquire the data at a rate 94 (FIG. 16) dependent upon temporal variations (or variability) in the scene, but then to process the data for display at a rate 100 appropriate for human visual response. For example acquisition may have to be very rapid if the camera is operating on a rapidly moving aerial platform, and the ideal display rate for best cognitive appreciation then corresponds, in effect, to a slow-motion playback.

In other situations exactly the opposite temporal relationships may be preferable. One example is the kind of stop-action photography, with much more rapid playback, used to display very slow natural processes.

It will be understood that moving-picture playback is compatible with flicker display, and it is only necessary to decide what flicker rate (usually about one-tenth of the video frame rate) is preferred for conspicuous visibility of the polarization-signature flicker within the moving-picture scene.

Major systems—Some additional specifics appear here for two principal systems that are preferred embodiments of the invention. First, for the more highly preferred camera system including a polarization mosaic with a single multispectral imaging array, the system includes an imaging lens 1 (FIG. 11) and the polarization mosaic 2. (As will be explained shortly, the mosaic 2 may represent a sandwich of the mosaic with several other optical-processing layers that perform respective corrections.)

Also included in this preferred embodiment is the Foveon multispectral imaging array 3. We prefer to provide an inertial measurement unit (“IMU”) 4 for measuring the camera optical-axis (or “boresight”) attitude, as well as a global positioning system (“GPS”) 5 for establishing the camera location.

In the most highly preferred embodiment we also include a timebase module 6 for triggering the camera, and for synchronizing image data, IMU data, and GPS data. More specifically, the timebase unit operates the camera trigger 7.

This system generates image data 8, IMU data 9, GPS data 10 and a time tag 11. Provided for handling these data is a data-acquisition-and-control subsystem 12 that simultaneously records image, camera location (GPS), camera pointing (IMU), and time. The system also controls several conventional camera functions such as exposure time.

This acquisition-and-control subsystem in turn feeds both a data-recording subsystem 13, which records all the above-mentioned raw data, and a real-time processing subsystem 14. Optional, for use in a staffed aircraft or other facility, is a real-time display 15.

On the other hand, where processing at a remote location is desired the preferred embodiment includes a radio-frequency link 16 to relay data for processing at remote locations. Associated with this form of the invention are a transmitter antenna 17, receiver antenna 18, and real-time display 19 for a remote operator (e. g. in UAV applications).

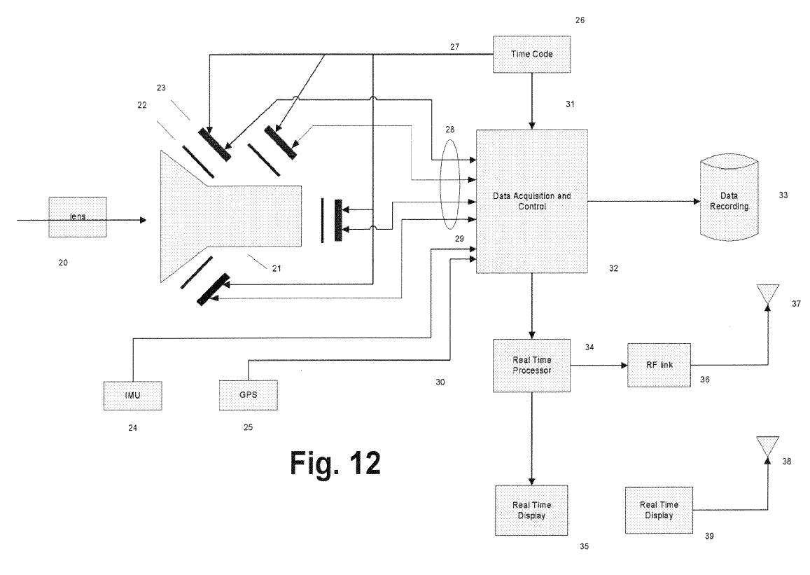

For our next-most-highly preferred embodiment, using an image-splitter prism with multiple multispectral imaging arrays, the corresponding system includes—as before—an imaging lens 20 (FIG. 12). Here, however, the second component in the optical train is an image-splitter prism 21, 44a-d (FIGS. 2 and 3).

This embodiment also includes four linear or circular polarizers 22. These are oriented in alternate configurations so that each multispectral imaging array receives a different polarization aspect (i. e. the successive arrays receive alternate linear or circular polarization states).

Correspondingly provided are four multispectral imaging arrays 23. The four polarizers respectively feed these imaging arrays.

As in the single-image-array system discussed above, this embodiment also includes an inertial measurement unit 24 to measure camera-axis attitude, a GPS 25 to measure camera location, and a timebase 26 to trigger the four cameras—and to synchronize image data, IMU data, and GPS data. In this case, four camera triggers 27 are required.

Resulting from operation of these components are image data 28—collected at four places—and IMU data 29, GPS data 30, and a time tag 31. As above, a data-acquisition-and-control subsystem 32 simultaneously records image, camera location (GPS), camera pointing (IMU), and time; this subsystem also controls camera functions such as exposure time.

In this case, trigger time and exposure time for each camera may be controlled independently, to facilitate normalization of the alternate polarization states, if desired, and to optimize temporal correlation. Also included are a data-recording subsystem 33, to record all raw data (images, time, position, pointing), and a real-time processing subsystem 34.

For a staffed system, this particular embodiment also includes a local real-time display 35. Again optionally for remote processing our invention provides a radio frequency link 36, to relay data via a transmitter antenna 37 and receiver antenna 38—as well as a real-time display for a remote operator.

### NOTES

1. C. S. L. Chun and F. A. Sadjadi, “Polarimetric imaging system for automatic target detection and recognition,” presented at the Military Sensing Symposia Specialty Group of Passive Sensors, Mar. 22, 2000
2. http://www.foveon.com
3. http://www.opticvalleyphotonics.com
4. E. P. G. Smith et al., “HgCdTe Focal Plane Arrays for Dual-Color Mid- and Long-Wavelength Infrared Detection,” Journal of Electronic Materials 33, No. 6 (2004).
5. J. D. Barter, H. R. Thompson, C. L. Richardson, “Visible-Regime Polarimetric Imager: A Fully Polarimetric, Real-Time Imaging System”, Applied Optics 42 No. 9 (March 2003)
6. J. Millerd et al., “Pixelated phase-mask dynamic interferometer”, SPIE 2004
7. J. Gou et al., “Fabrication of thin-film micropolarizer arrays for visible imaging polarimetry”, Applied Optics 39 No. 10 (2000)
8. J. D. Barter et al., n. 5 supra
9. F. Sadjadi and C. Chun, “Remote sensing using passive infrared Stokes parameters”, Opt. Eng. 43 No. 10 (2004)
10. J. Millerd et al., n. 6 supra
11. J. Gou et al., n. 7 supra
12. http://www.foveon.com
13. http://www.opticvalleyphotonics.com
14. J. D. Barter et al., n. 5 supra
15. Nordin et al., “Micropolarizer array for infrared imaging polarimetry”, J. Opt. Soc. AmA 16 No. 5 (1999)
16. J. Gou et al., n. 7 supra
17. J. Millerd et al., n. 6 supra
18. M. Colburn et al., “Step and flash imprint lithography for sub-100 nm patterning”, Proc SPIE
19. J. Gou et al., n. 4 supra
20. Julia M. Laurenzano, “A Comparative Analysis of Spectral Band Selection Techniques”, MS thesis, Rochester Institute of Technology (1998).
21. I. S. Reed and X. Yu, “Adaptive Multiple-band CFAR Detection of an Optical Pattern with Unknown Spectral Distribution”, IEEE Transactions on acoustics, speech, and signal processing 38, No. 10 (October 1990).
22. K. M. Yemelyanov et al., “Bio-inspired display of polarization information using selected visual cues,” Proceedings of SPIE 5158 (Polarization Science and Remote Sensing (Bellingham Wash., 2003)

In certain of the accompanying apparatus claims the term “such” is used as a specialized kind of definite article (instead of “said” or “the”) in the bodies of the claims, when reciting elements of the claimed invention, for referring back to features which are introduced in preamble as part of the context or environment of the claimed invention. The purpose of this convention is to aid in more distinctly and emphatically pointing out which features are elements of the claimed invention, and which are instead parts of its context—and thereby to more particularly claim the invention.

In the accompanying claims the term “substantially”, too, is used with a special meaning: this word excludes from consideration only departures, from the remaining language of a claim, that are employed (e. g. by a competitor) with evidently a primary purpose of avoiding the claim. Thus “substantially” causes the claim to encompass apparatus or method that has a modification, especially but not only a minor modification, that serves only or mainly to escape the claim, and apparently confers little or no significant technological benefit. For example “substantially only a single array of pixels” encompasses a device in which a separate array or cluster of one or more pixels appears without apparent purpose other than a hope of designing around the claim. Analogously “substantially ambient radiation” encompasses radiation having some essentially insignificant admixture of nonambient radiation—again evidently just in hopes of avoiding the claim. Hence the term “substantially” is meant for interpretation primarily in connection with enforcement or licensing and in general can be disregarded for purposes of examination.

It will be understood that the foregoing disclosure is intended to be merely exemplary, and not to limit the scope of the invention—which is to be determined by reference to the appended claims.

We claim:

1. Apparatus for multispectral and multipolarization imaging; said apparatus comprising:
first means for recording at least one multispectral image of a scene, wherein a multispectral image comprises multiple different wavelengths or colors;
the recording means comprising means for discriminating among at least some of said multiple different wavelengths or colors in the scene;
the recording and discriminating means comprising exactly one array of sensors, wherein the sensor array records one multispectral image of the scene; said recording and discriminating means comprising means for recording all pixels of the multispectral image mutually simultaneously; and
second means for, simultaneously with said recording, determining polarization state of the image at corresponding points of the exactly one array; wherein:
the first and second means operate using radiation collected through a single aperture, in common; and
a single aperture is an aperture that does not have plural optical apertures in parallel.

2. The apparatus of claim 1, wherein:
the single aperture can have plural optical apertures in series.

3. The apparatus of claim 1, wherein:
said collected radiation is incoherent radiation; and
the apparatus comprises no radio-frequency modulator, and no means for vibrationally inducing diffractive fringes.

4. The apparatus of claim 1, wherein:
the exactly one sensor array comprises multiple sensor-array planes, responsive in multiple spectral regions respectively, for recording the one image as substantially a single array of pixels, and for spectrally analyzing the multispectral image;
the second means comprise means for selecting or defining a different polarization state for different regions of the image respectively; and
wherein the second means determine and record polarization state at substantially every pixel of the multispectral image.

5. The apparatus of claim 4, wherein:
the multiple sensor-array planes are permanently in contact with each other and therefore inherently in register with each other; and
the selecting or defining means are permanently in contact with the exactly one sensor array and therefore inherently in register with the exactly one sensor array.

6. The apparatus of claim 5, wherein:
the selecting or defining means comprise at least one mosaic of differently oriented polarizers overlaying the sensor array.

7. The apparatus of claim 6, wherein:
the polarizer mosaic is formed as a wire-grid array.

8. The apparatus of claim 6, wherein:
the polarizer mosaic is formed of polarizing thin films.

9. The apparatus of claim 6, wherein:
said single, multispectral sensor array comprises plural sensor-array layers respectively responsive to plural wavelength regions or colors.

10. The apparatus of claim 9, wherein:
the polarizer mosaic is formed of multiple unit cells, each unit cell being two pixels by two pixels; and
the two-by-two unit cells comprise linear polarizers.

11. The apparatus of claim 10, wherein:
the linear polarizers are oriented at zero, forty-five, ninety and one hundred thirty-five degrees respectively.

12. The apparatus of claim 6, wherein:
the polarizer mosaic comprises a combination of linear polarizers and neutral-density filters.

13. The apparatus of claim 6, wherein:
the polarizer mosaic comprises a combination of linear and circular polarizers, and neutral-density filters.

14. The apparatus of claim 6, wherein:
the polarizer mosaic is formed of multiple unit cells, each unit cell being three pixels.

15. The apparatus of claim 14, wherein:
each three-pixel unit cell comprises linear polarizers.

16. The apparatus of claim 14, wherein:
each three-pixel unit cell comprises a combination of linear polarizers and neutral-density filters.

17. The apparatus of claim 14, wherein:
each three-pixel unit cell comprises a combination of linear and circular polarizers, and neutral-density filters.

18. The apparatus of claim 6, wherein:
the polarizer mosaic is bonded to the sensor array.

19. The apparatus of claim 6, wherein:
the polarization mosaic is lithographically integrated into the chip, in fabrication.

20. The apparatus of claim 6, wherein:
the polarizer mosaic comprises microlenses incorporated to enhance fill factor or reduce aliasing, or both.

21. The apparatus of claim 20, wherein:
the polarizer mosaic further comprises spectral filters incorporated to optimize spectral response.

22. The apparatus of claim 1, further comprising:
display means for successively presenting the multispectral image with different polarization-state information included;
whereby image portions having polarization states different from one another appear to flicker.

23. The apparatus of claim 1, further comprising:
means for trading-off resolution against frame rate, for acquisition of multiple sequential image data sets corresponding to a motion picture;
wherein said trading-off means comprise means for increasing resolution while decreasing frame rate, or increasing frame rate while decreasing resolution, to maintain generally constant total information acquired per unit time; and
means for controlling frame acquisition rates of the acquisition means, in accordance with characteristics of the scene or of the acquisition process;
wherein said collected radiation is substantially ambient radiation.

24. Apparatus for acquisition, and preparation for display, of a multispectral, multipolarization motion picture; said apparatus comprising:
means for acquisition and recording, through a single optical aperture, in common, of successive multispectral, multipolarization image frames, wherein a multispectral, multipolarization image frame is an image frame comprising multiple different wavelengths or colors and plural polarization states;
a single optical aperture being an aperture that does not comprise plural optical apertures in parallel;
said acquisition-and-recording means comprising means for discriminating among at least some of said multiple different wavelengths or colors in the image frames, and among at least some of said polarization states in the image frames; and
means for controlling frame acquisition rates of the acquisition means, in accordance with characteristics of the scene or of an acquisition process.

25. The apparatus of claim 24, wherein:
the single aperture can have plural optical apertures in series.

26. The apparatus of claim 24, wherein:
said recording and discriminating means comprise means for recording all pixels of the multispectral image mutually simultaneously.

27. The apparatus of claim 24, wherein:
the apparatus comprises no means for vibrationally inducing diffractive fringes, and no radio-frequency modulator.

28. The apparatus of claim 24:
wherein said acquisition-and-recording means comprising a single, multispectral sensor array comprises plural sensor-array layers respectively responsive to plural wavelength regions or color bands; and further comprising:
means for playing back the recorded frames for human observation;
said playback means comprising means for controlling frame display rates in accordance with perceptual characteristics of human observers of the motion picture.

29. The apparatus of claim 28, wherein the playback means further comprise:
display means for successively presenting the successive image frames with different polarization-state information included and with said multiple different wavelengths or colors sensed by the plural sensor-array layers being respectively presented by the display means as spectrally corresponding multiple wavelengths or colors in each image frame;
a whereby image portions having polarization states different from one another appear to flicker.

30. Apparatus for multispectral and multipolarization imaging; said apparatus comprising:
first means, operating with substantially only ambient radiation, for recording a multispectral image of a scene, wherein a multispectral image is an image comprising multiple different wavelengths or colors;
said recording means comprising means for discriminating among at least some of said multiple different wavelengths or colors in the scene; and
second means, also operating with substantially only ambient radiation, for establishing a polarization-state image of the same scene;
wherein the first and second means share a common radiation-sensor array.

31. The apparatus of claim 30, wherein:
the first and second means further are functionally coordinated to render the inherently-in-register polarization and multispectral images mutually simultaneous.

32. The apparatus of claim 30, wherein:
the common array is a monolithic device that causes the polarization image to be inherently in register with the multispectral image.

33. The apparatus of claim 30, wherein:
the first and second means respectively provide spectrally-selective and polarization-selective elements to modulate response of the shared common radiation-sensor array.

34. The apparatus of claim 30, wherein:
the first and second means collect all of the multispectral image and all of the polarization-state image through a single, common aperture;
the single aperture does not comprise plural optical apertures in parallel; and
the single aperture can have plural optical apertures in series.

35. The apparatus of claim 30, wherein:
said recording and discriminating means comprise means for recording all pixels of the multispectral image mutually simultaneously.

36. The apparatus of claim 30, wherein:
the apparatus comprises no means for vibrationally inducing diffractive fringes, and no radio-frequency modulator.

37. A digital camera for plural-wavelength-band imaging with polarization information included; said camera comprising:
an imaging sensor chip that is sensitive to optical radiation in at least two wavelength bands that substantially are mutually distinct, for recording an image;
said chip having a plurality of sensitive layers, each layer disposed substantially continuously across a field of view, and each layer being spectrally responsive respectively to a particular one of the at least two wavelength bands;
wherein the sensitive layers for each of the bands, respectively, enable the sensor chip to discriminate spectrally among the bands of the radiation;
said sensitive layers being stacked in series, so that incoming radiation in at least one of the at least two bands penetrates plural layers to reach a spectrally corresponding sensitive layer;
a polarization mosaic overlaid on the stack of sensitive layers, also substantially continuously across the field of view;
said mosaic defining an array of superpixels that impose polarization-state differentiation on the sensitive layers; and
an electronic shutter to actuate the sensitive layers for exposure through the polarization mosaic for calibrated time periods, to acquire information for the image in said distinct wavebands with polarization information included;
the camera having no means for vibrationally inducing diffractive fringes.

38. The apparatus of claim 37, further comprising:
display means for successively presenting the image with different polarization-state information included;
whereby image portions that include polarization states different from one another appear to flicker.

39. The apparatus of claim 37, further comprising:
means for trading-off resolution against frame rate, for acquisition of multiple sequential image data sets corresponding to a motion picture;
wherein said trading-off means comprise means for increasing resolution while decreasing frame rate, or increasing frame rate while decreasing resolution, to maintain generally constant total information acquired per unit time; and
means for controlling frame acquisition rates of the acquisition means, in accordance with characteristics of the scene or of the acquisition process.

40. The apparatus of claim 39, wherein:
the at least two wavebands comprise at least three wavebands.

41. The apparatus of claim 37, wherein:
said optical radiation is substantially incoherent radiation; and
the sensor chip comprises means for recording all parts of the image mutually simultaneously.

42. The apparatus of claim 41, wherein:
the substantially incoherent radiation is substantially exclusively ambient radiation;
the first and second means collect all of the multispectral image and all of the polarization-state image through a single, common aperture;
the single aperture does not comprise plural optical apertures in parallel; and
the single aperture can have plural optical apertures in series.

43. An image system comprising:
means for generating a temporal sequence of spatially registered multispectral, multipolarization images, wherein said multispectral, multipolarization images each comprise multiple wavelength bands or colors, and plural polarization states;
wherein the generating means operate using substantially only incoherent radiation, and comprise means for discriminating among the wave-length bands or colors, and among the polarization states, and means for temporally sampling at a sampling rate to form said sequence; and
the image system having no radio-frequency modulator.

44. The system of claim 43, further comprising:
means for modifying the sampling means to trade off spatial samples for temporal samples;
wherein said modifying means comprise means for increasing the number of spatial samples while decreasing the number of temporal samples, or increasing the number of temporal samples while decreasing the number of spatial samples, to maintain generally constant total information acquired per unit time;
whereby the sampling means vary the sampling rate.

45. The apparatus of claim 44, further comprising:
operator-controlled means for setting the modifying means to establish a desired sampling rate.

46. The apparatus of claim 43, particularly for use in imaging at least one object; and wherein:
the generating means comprise means for defining the temporal sequence as viewing such at least one object from multiple viewpoints.

47. The apparatus of claim 43, particularly for use in imaging a scene; and wherein:
the generating means comprise means for defining the temporal sequence as viewing historical development of such scene.

48. The apparatus of claim 43, particularly for use in imaging a scene; and wherein:
the substantially incoherent radiation substantially is exclusively ambient radiation;
the generating means comprise means for defining the temporal sequence as viewing historical development of such scene from multiple viewpoints.

49. Apparatus for multispectral and multipolarization imaging; said apparatus comprising:
means for acquiring data representing at least one multispectral image of a scene, including information that establishes polarization state at all or most points of the image; wherein:
said at least one multispectral image comprises multiple different wavelengths or color bands; and the data comprise multiple data categories corresponding to the different wavelengths or color bands respectively; and
the data-acquiring means comprise means for discriminating among the data corresponding to the respective wavelengths or color bands; and
said acquiring means comprising a single optical aperture for passage of all optical rays used in formulating the multispectral-image and polarization-state data.

50. The apparatus of claim 49, wherein the acquiring means:
operate using substantially only incoherent ambient radiation; and
comprise means for recording all parts of the image, including said polarization information, mutually simultaneously.
